(19) United States
(12) Patent Application Publication
(10) Pub. No.: US 2015/0251398 A1
(43) Pub. Date: Sep. 10, 2015

(54) BONDING SYSTEM AND BONDING METHOD

(71) Applicant: TOKYO ELECTRON LIMITED, Tokyo (JP)

(72) Inventors: Masatoshi DEGUCHI, Kikuchi-gun (JP); Takashi SAKAUE, Kikuchi-gun (JP); Hiroshi NAGATA, Kikuchi-gun (JP); Kei TASHIRO, Kikuchi-gun (JP)

(21) Appl. No.: 14/633,879

(22) Filed: Feb. 27, 2015

(30) Foreign Application Priority Data
Mar. 4, 2014 (JP) 2014-042171

(51) Int. Cl. B32B 37/02; B32B 37/12; B32B 38/00; H01L 21/683; B32B 7/12; B32B 37/06; B32B 37/10; B32B 37/00; B32B 7/06

(52) U.S. Cl. CPC B32B 37/02; B32B 37/0038; B32B 37/1284; B32B 38/105; B32B 7/06; B32B 7/12; B32B 37/06; B32B 37/10; H01L 21/6835; B32B 2457/14; H01L 2221/68381; H01L 2221/68327

(57) ABSTRACT

Provided is a bonding system, which includes: a processing station in which specified processes are performed on a first substrate and a second substrate; and a carry-in/carry-out station in which the first substrate, the second substrate or a laminated substrate obtained by bonding the first substrate and the second substrate is carried into and out of the processing station. The processing station includes: a first processing apparatus configured to coat the first substrate with the bonding agent using a bonding agent injecting part; a second processing apparatus provided with a bevel cleaning unit for cleaning a bevel portion of the first substrate coated with the bonding agent; and a bonding apparatus configured to bond the first substrate and the second substrate through the bonding agent and a release agent. The first processing apparatus or the second processing apparatus further includes a release agent injection part for injecting the release agent.

### CROSS-REFERENCE TO RELATED APPLICATION

This application claims the benefit of Japanese Patent Application No. 2014-042171 filed on Mar. 4, 2014, in the Japan Patent Office, the disclosure of which is incorporated herein in its entirety by reference.

### TECHNICAL FIELD

The present disclosure relates to a bonding system and a bonding method.

### BACKGROUND

In recent years, for example, in a semiconductor device manufacturing process, target substrates such as a silicon wafer, a compound semiconductor wafer and the like become larger in diameter and thinner in thickness. A target substrate having a large diameter and a thin thickness may have a warp or a crack during a transfer operation or a polishing process. As such, the target substrate is reinforced by bonding a support substrate such as a glass substrate to the target substrate.

For example, there is known a bonding system which includes: an bonding agent coating apparatus for widely coating an bonding agent on a surface of a target substrate; a release agent coating apparatus for widely coating a release agent smaller in bonding force than the bonding agent on a surface of a support substrate; a heat treatment apparatus for heating the target substrate coated with the bonding agent or the support substrate coated with the release agent, and a bonding apparatus for bonding the target substrate and the support substrate, which have been subjected to the heat treatment, through the bonding agent and the release agent.

However, in the conventional bonding system, there is a room for further improvement in that the number of apparatuses needs to be reduced while preventing a decrease in throughput.

For example, in the related art, a series of processes which includes widely coating an bonding agent on a surface of a target substrate; widely coating a release agent on a surface of a support substrate; and injecting a cleaning liquid toward a rear surface of the target substrate to clean a periphery of the target substrate, are performed in a single apparatus. However, this prolongs a process time required for performing the processes by the single apparatus, which results in a reduced throughput of the bonding process.

### SUMMARY

The present disclosure provides some embodiments of a bonding system and a bonding method which are capable of reducing the number of apparatuses while preventing a decrease in throughput.

According to one embodiment of the present disclosure, there is provided a bonding system, including: a processing station in which specified processes are performed on a first substrate and a second substrate; and a carry-in/carry-out station in which the first substrate, the second substrate or a laminated substrate obtained by bonding the first substrate and the second substrate is carried into and out of the processing station, wherein the processing station includes: a first processing apparatus provided with an bonding agent injection part for injecting an bonding agent and configured to coat the first substrate with the bonding agent using the bonding agent injecting part; a second processing apparatus provided with a bevel cleaning unit for cleaning a bevel portion of the first substrate coated with the bonding agent; and a bonding apparatus configured to bond the first substrate and the second substrate through the bonding agent and a release agent which is smaller in bonding force than the bonding agent, wherein the first processing apparatus or the second processing apparatus further includes a release agent injection part for injecting the release agent, and is configured to coat the release agent on the second substrate using the release agent injecting part.

According to another embodiment of the present disclosure, there is provided a bonding method, including: a first coating process in which a bonding agent is coated on a first substrate using a first processing apparatus provided with a bonding agent injection part for injecting the bonding agent; a bevel cleaning process in which a bevel portion of the first substrate subjected to the first coating process is cleaned using a second processing apparatus provided with a bevel cleaning unit for cleaning the bevel portion of the first substrate; a second coating process in which a release agent lower in bonding force than the bonding agent is coated on a second substrate using a release agent injection part for injecting the release agent; and a bonding process in which the first substrate and the second substrate are bonded through the bonding agent and the release agent, wherein the second coating process is performed in the first processing apparatus or the second processing apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plane view showing a configuration of a bonding system according to a first embodiment of the present disclosure.

FIG. 2 is a schematic side view of a target substrate and a support substrate.

FIG. 3 is a schematic side view showing a configuration of a first coating apparatus.

FIG. 4 is a schematic side view showing a configuration of a second coating apparatus.

FIG. 5 is a schematic side view showing a configuration of a heat treatment apparatus.

FIG. 6 is a schematic plane view showing the configuration of the heat treatment apparatus shown in FIG. 5.

FIG. 7 is a schematic side view showing a configuration of an edge cut apparatus.

FIG. 8 is a schematic perspective view showing the configuration of the edge cut apparatus shown in FIG. 7.

FIG. 9 is a schematic plane view showing a configuration of a bonding apparatus.

FIG. 10 is a schematic side view showing a configuration of a bonding unit.

FIG. 11 is a flowchart showing a sequence of processes which are performed by the bonding system according to the first embodiment.

FIG. 12 is a flowchart showing a sequence of an inspecting/recleaning process.

FIG. 13 is a view showing an exemplary operation of a bonding process.

FIGS. 14 to 16 are views showing a relationship between respective processes and apparatuses for performing a respective process.

FIG. 17 is a schematic side view of a target substrate and a support substrate according to a second embodiment.

FIG. 18 is a schematic side view showing a bonding surface of a target substrate coated with a release agent.

FIG. 19 is a schematic side view showing a bonding surface of a target substrate coated with a protective agent and a release agent.

FIG. 20 is a schematic side view showing a configuration of a first coating apparatus according to a third embodiment.

FIG. 21 is a flowchart showing a sequence of processes which are performed by a bonding system according to a fourth embodiment.

FIG. 22 is a view showing a relationship between respective processes and apparatuses for performing a respective process.

FIG. 23 is a flowchart showing a sequence of a bonding process and a temporary hardening process according to a fifth embodiment.

FIG. 24 is a schematic plane view showing a configuration of a bonding system according to a sixth embodiment.

FIGS. 25 and 26 are schematic side views showing a configuration of a temporary hardening apparatus according to the sixth embodiment.

FIG. 27 is a schematic side view showing a configuration of a second coating apparatus according to a seventh embodiment.

FIG. 28 is a schematic side view showing a configuration of an inspection unit according to a modified example.

### DETAILED DESCRIPTION

Reference will now be made in detail to various embodiments of a bonding method and a bonding system, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

### 1. Configuration of Bonding System

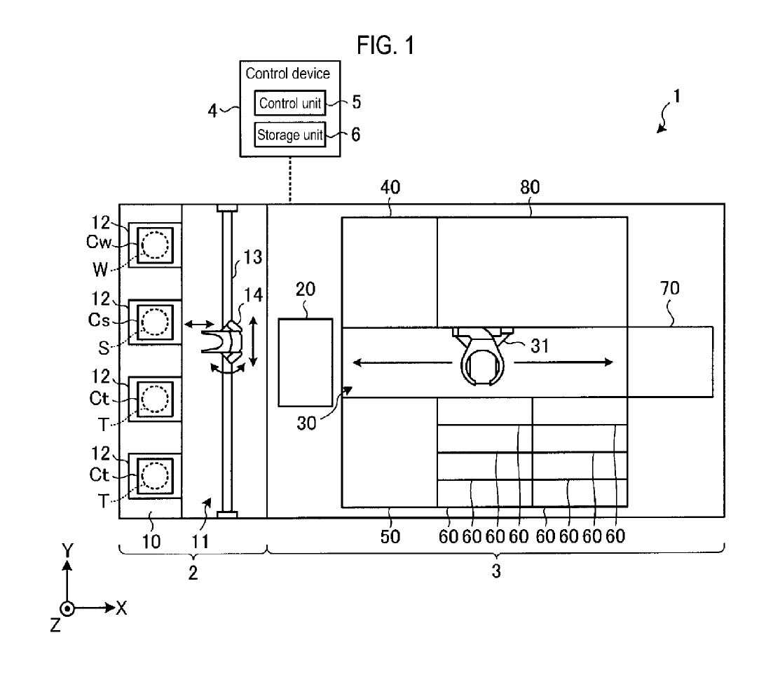

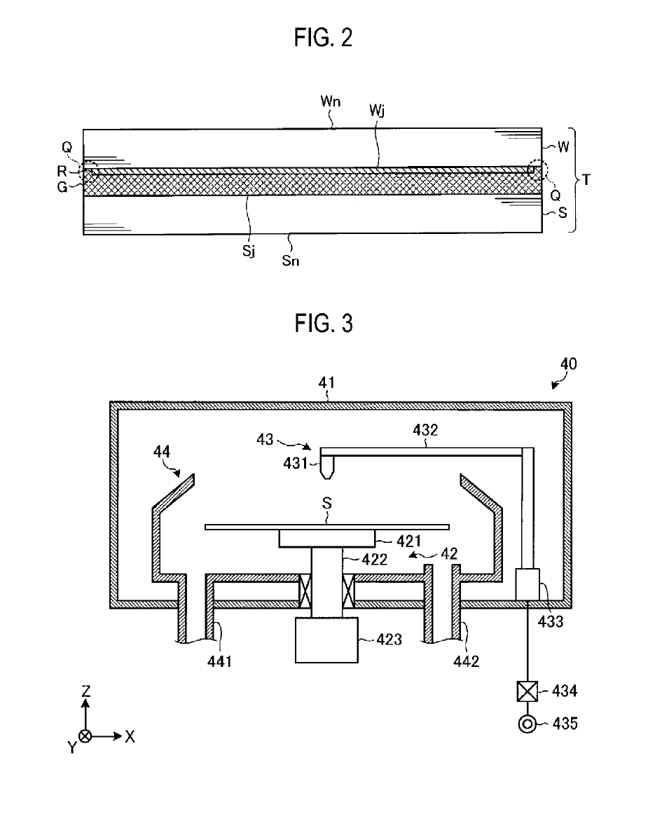

First, a configuration of a bonding system according to a first embodiment will be described with reference to FIGS. 1 and 2. FIG. 1 is a schematic plane view showing the configuration of the bonding system according to the first embodiment. FIG. 2 is a schematic side view of a target substrate and a support substrate. For the clarification of a positional relationship, an X-axis direction, a Y-axis direction and a Z-axis direction, which are orthogonal to one another, are defined in the following description, and a forward direction of the Z-axis direction is defined as a vertical upward direction.

The bonding system 1 shown in FIG. 1 is configured to form a laminated substrate T by bonding a target substrate W and a support substrate S using a bonding agent G and a release agent R (see FIG. 2).

The target substrate W is a substrate made by forming a plurality of electronic circuits on a semiconductor substrate such as a silicon wafer, a compound semiconductor wafer or the like. A surface of the target substrate W, on which the electronic circuits are formed, will be defined as a bonding surface Wj which is bonded to the support substrate S. The opposite surface of the bonding surface Wj will be defined as a non-bonding surface Wn. The target substrate W structured as above, after being bonded to the support substrate S, is thinned by polishing the non-bonding surface Wn. The release agent R is coated on the bonding surface Wj of the target substrate W.

On the other hand, the support substrate S has a diameter approximately equal to a diameter of the target substrate W and supports the target substrate W. A glass substrate, the semiconductor substrate or the like may be used as the support substrate S. The bonding agent G is coated on a bonding surface Sj of the support substrate S, which is bonded to the target substrate W.

The bonding agent G may be a thermosetting resin-based bonding agent. A thermosetting property means that a material is hard to be deformed at a normal temperature (e.g., about 20 degrees C.) but is easy to be soften and molded by heat. Further, the thermosetting property means that a material is polymerized and hardened by being subjected to further heat treatment, which becomes irreversible. Examples of the bonding agent G used in the bonding system 1 may include a material having a softening temperature of about 120 to 140 degrees C. and a hardening temperature of about 180 degrees C.

The release agent R is applied to smoothly delaminate (or separate) the target substrate W from the support substrate S when the laminated substrate T is separated into the target substrate W and the support substrate S. Examples of the release agent R may include a material which is smaller in bonding force and lower in viscosity than the bonding agent G. The release agent R is predisposed to be soluble in an organic solvent such as a thinner, and to be not hardened even when heated.

A region from which the release agent R is removed (hereinafter referred to as an “uncoated region Q”) exists in a peripheral portion of the bonding surface Wj of the target substrate W. When the target substrate W and the support substrate S are bonded to each other by a bonding process (which will be described later), the bonding agent G coated on the support substrate S is filled into the uncoated region Q. Thus, the target substrate W and the support substrate S are strongly bonded to each other in the uncoated region Q by the bonding agent G. This prevents an occurrence of misalignment, for example, when the laminated substrate T is transferred.

The uncoated region Q is formed by coating the release agent R on the entire bonding surface Wj of the target substrate W, followed by performing an edge cut process of removing the release agent R from the peripheral portion (including a bevel portion) of the target substrate W. This will be described later.

As shown in FIG. 1, the bonding system 1 includes a carry-in/carry-out station 2 and a processing station 3 which are serially connected. The carry-in/carry-out station 2 and the processing station 3 are disposed in the named order in a forward side of the X-axis direction.

The carry-in/carry-out station 2 includes a cassette loading table 10 and a first transfer zone 11. On the cassette loading table 10, cassettes Cw, Cs and Ct in each of which a plurality of (e.g., 25) substrates is accommodated in a horizontal state, are loaded. The carry-in/carry-out station 2 includes, for example, four loading parts 12 which are arranged in a line. For example, the cassette Cw with the target substrates W, the cassette Cs with the support substrates S and the cassette Ct with the laminated substrates T, are loaded on the respective loading parts 12 of the carry-in/carry-out station 2.

In the first transfer zone 11, there are disposed a transfer path 13 extending in the Y-axis direction and a first transfer device 14 movable along the transfer path 13. The first transfer device 14 is movable in the X-axis and Y-axis directions and is rotatable about a Z-axis. The first transfer device 14 is configured to transfer the target substrate W, the support substrate S and the laminated substrate T between the cassettes Cw, Cs and Ct loaded on the loading parts 12, and a first delivery unit 20 (which will be described later).

The processing station 3 includes the first delivery unit 20, a second transfer zone 30, a first coating apparatus 40, a second coating apparatus 50, a plurality of heat treatment apparatuses 60, an edge cut apparatus 70, and a bonding apparatus 80.

The first delivery unit 20 is disposed between the first transfer zone 11 and the second transfer zone 30. In the first delivery unit 20, the target substrate W, the support substrate S and the laminated substrate T are delivered between the first transfer device 14 disposed in the first transfer zone 11 and a second transfer device 31 disposed in the second transfer zone 30.

The second transfer device 31 is disposed in the second transfer zone 30. The second transfer device 31 is movable in the X-axis and Y-axis directions and is rotatable about the Z-axis. The second transfer device 31 is configured to transfer the target substrate W, the support substrate S and the laminated substrate T between the first delivery unit 20, the first coating apparatus 40, the second coating apparatus 50, the heat treatment apparatuses 60, the edge cut apparatus 70 and the bonding apparatus 80.

The first coating apparatus 40 is configured to coat the bonding agent G on the bonding surface Sj of the support substrate S. The second coating apparatus 50 is configured to coat the release agent R on the bonding surface Wj of the target substrate W. The heat treatment apparatuses 60 are configured to heat the support substrate S coated with the bonding agent G or the target substrate W coated with the release agent R to a predetermined temperature. The edge cut apparatus 70 is configured to remove the release agent R from the peripheral portion of the target substrate W. The bonding apparatus 80 is configured to bond the target substrate W and the support substrate S using the bonding agent G and the release agent R.

The first coating apparatus 40, the second coating apparatus 50, the heat treatment apparatuses 60, the edge cut apparatus 70 and the bonding apparatus 80 are arranged around the second transfer zone 30. Specifically, the first coating apparatus 40 is located at a position near to the first delivery unit 20 in the Y-axis direction. The second coating apparatus 50 is located to face the first coating apparatus 40 with the second transfer zone 30 interposed therebetween. The bonding apparatus 80 is disposed adjacent to the first coating apparatus 40 in the X-axis direction. The heat treatment apparatuses 60 are disposed adjacent to the second coating apparatus 50 in the X-axis direction. The edge cut apparatus 70 is disposed to face the first delivery unit 20 with the second transfer zone 30 interposed therebetween.

The heat treatment apparatuses 60 are stacked at, e.g., four stages, in a vertical direction and are arranged, e.g., at two rows, in a left-right direction. The number and arrangement of the heat treatment apparatuses 60 may be arbitrarily set.

Further, the bonding system 1 includes a control device 4. The control device 4 controls the entire operation of the bonding system 1. The control device 4 is, for example, a computer, and includes a control unit 5 and a storage unit 6. The storage unit 6 stores a program which controls various processes such as the bonding process and the like. The control unit 5 is, e.g., a CPU (Central Processing Unit), and is configured to read out and execute the program stored in the storage unit 6, thereby controlling the entire operation of the bonding system 1.

Further, the aforementioned program may be stored in a computer-readable recording medium and may be installed from the recording medium into the storage unit 6 of the control device 4. Examples of the computer-readable recording medium may include a hard disk (HD), a flexible disk (FD), a compact disk (CD), a magneto-optical disk (MOD), a memory card, and the like. The control unit 5 may be configured only by hardware without having to use a program.

<2. Configuration of First Coating Apparatus>

Next, the configuration of the first coating apparatus 40 will be described with reference to FIG. 3. FIG. 3 is a schematic side view showing the configuration of the first coating apparatus 40.

As shown in FIG. 3, the first coating apparatus 40 includes a chamber 41, a substrate holding mechanism 42, a liquid supply unit 43, and a collection cup 44.

The chamber 41 accommodates the substrate holding mechanism 42, the liquid supply unit 43 and the collection cup 44. An FFU (Fan Filter Unit) (not shown) is installed in a ceiling portion of the chamber 41. The FFU is provided to form a down flow within the chamber 41.

The substrate holding mechanism 42 is installed substantially at the center of the chamber 41 and includes a holding unit 421, a post member 422 and a drive unit 423.

The holding unit 421 is, e.g., a porous chuck, and adsorptively holds the support substrate S. The post member 422 is a member extending in the vertical direction, a base end portion of which is rotatably supported by the drive unit 423 and a tip portion of which horizontally supports the holding unit 421. The drive unit 423 rotates the post member 422 about a vertical axis. The substrate holding mechanism 42 rotates the post member 422 using the drive unit 423, thereby rotating the holding unit 421 supported on the post member 422. Thus, the support substrate S held by the holding unit 421 is rotated. The support substrate S is held by the substrate holding mechanism 42 with the bonding surface Sj thereof oriented upward.

The liquid supply unit 43 supplies the bonding agent G to the support substrate S held by the substrate holding mechanism 42. The liquid supply unit 43 includes a bonding agent injection part 431, an arm 432 configured to horizontally support the bonding agent injection part 431, and a rotation/elevation mechanism 433 configured to rotate and vertically move the arm 432. The bonding agent injection part 431 is coupled to a bonding agent supply source 435 through a valve 434 such that the bonding agent G supplied from the bonding agent supply source 435 is injected onto the support substrate S.

In order to reduce the viscosity of the bonding agent G and to easily spread the bonding agent G on the support substrate S, an organic solvent such as a thinner may be mixed with the bonding agent G injected from the bonding agent injection part 431.

The collection cup 44 is disposed to surround the holding unit 421 and is configured to collect the bonding agent G scattered from the support substrate S during the rotation of the holding unit 421. A liquid discharge port 441 is formed at a bottom portion of the collection cup 44. The bonding agent G collected by the collection cup 44 is discharged to the outside of the first coating apparatus 40 through the liquid discharge port 441. An exhaust port 442 through which a down flow gas supplied from the FFU (not shown) is drained to the outside of the first coating apparatus 40, is formed in the bottom portion of the collection cup 44.

In the first coating apparatus 40 configured as above, the substrate holding mechanism 42 rotates the support substrate S, and the liquid supply unit 43 supplies the bonding agent G onto the bonding surface Sj of the support substrate S rotating by the substrate holding mechanism 42. The bonding agent G supplied onto the bonding surface Sj of the support substrate S is spread over the entire bonding surface Sj of the support substrate S by a centrifugal force generated due to the rotation of the support substrate S. Thus, a coating film of the bonding agent G is formed on the bonding surface Sj of the support substrate S.

<3. Configuration of Second Coating Apparatus>

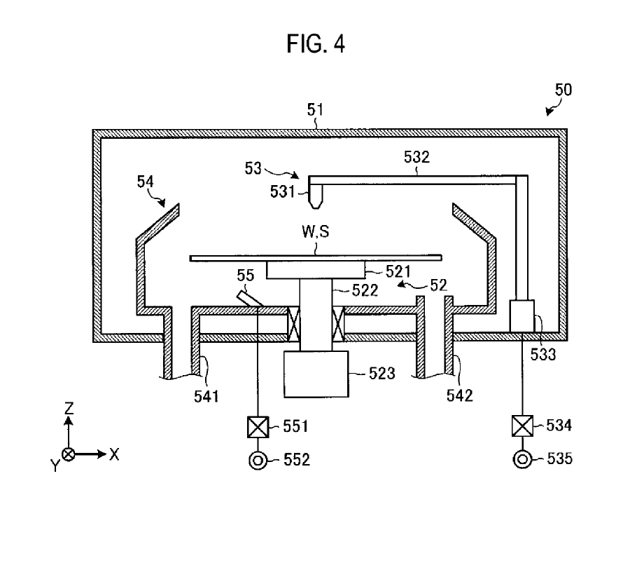

Next, a configuration of the second coating apparatus 50 will be described with reference to FIG. 4. FIG. 4 is a schematic side view showing the configuration of the second coating apparatus 50.

As shown in FIG. 4, the second coating apparatus 50 includes a chamber 51, a substrate holding mechanism 52, a liquid supply unit 53, and a collection cup 54. The chamber 51, the substrate holding mechanism 52 and the collection cup 54 of the second coating apparatus 50 are identical in configuration with those of the first coating apparatus 40. Specifically, the substrate holding mechanism 52 includes a holding unit 521, a post member 522 and a drive unit 523. The collection cup 54 includes a liquid discharge port 541 and an exhaust port 542. The target substrate W is held by the substrate holding mechanism 52 with the bonding surface Wj thereof oriented upward.

The liquid supply unit 53 includes a release agent injection part 531, an arm 532 configured to horizontally support the release agent injection part 531, and a rotation/elevation mechanism 533 configured to rotate and vertically move the arm 532. The release agent injection part 531 is coupled to a release agent supply source 535 through a valve 534 such that the release agent R supplied from the release agent supply source 535 is injected onto the target substrate W.

Similarly, in order to reduce the viscosity of the release agent R and to easily spread the release agent R on the target substrate W, an organic solvent such as a thinner may be mixed with the release agent R injected from the release agent injection part 531.

In the second coating apparatus 50 configured as above, the substrate holding mechanism 52 rotates the target substrate W, and the liquid supply unit 53 supplies the release agent R onto the bonding surface Wj of the target substrate W rotating by the substrate holding mechanism 52. The release agent R supplied onto the bonding surface Wj of the target substrate W is spread over the entire bonding surface Wj of the target substrate W by a centrifugal force generated due to the rotation of the target substrate W. Thus, a coating film of the release agent R is formed on the bonding surface Wj of the target substrate W.

The second coating apparatus 50 further includes a bevel cleaning unit 55. The bevel cleaning unit 55 according to the first embodiment is used in removing the bonding agent G adhering to a bevel portion of the support substrate S.

The bevel cleaning unit 55 is installed below the support substrate S held by the substrate holding mechanism 52, e.g., in the bottom portion of the collection cup 54. The bevel cleaning unit 55 is coupled to a chemical solution supply source 552 through a valve 551 such that a chemical solution (the organic solvent such as the thinner, in this embodiment) supplied from the chemical solution supply source 552 is discharged toward a peripheral portion of a rear surface of the support substrate S.

In the second coating apparatus 50, the substrate holding mechanism 52 holds and rotates the support substrate S. The bevel cleaning unit 55 supplies the organic solvent toward the peripheral portion of the rear surface of the support substrate S under rotation. The organic solvent supplied to the peripheral portion of the rear surface of the support substrate S flows from the rear surface of the support substrate S toward the front surface thereof, thereby dissolving the bonding agent G adhering to the bevel portion of the support substrate S and removing the bonding agent G therefrom.

As described above, the second coating apparatus 50 according to the first embodiment performs cleaning the bevel portion of the support substrate S, in addition to coating the release agent R onto the target substrate W. This will be described below.

<4. Configuration of Heat Treatment Apparatus>

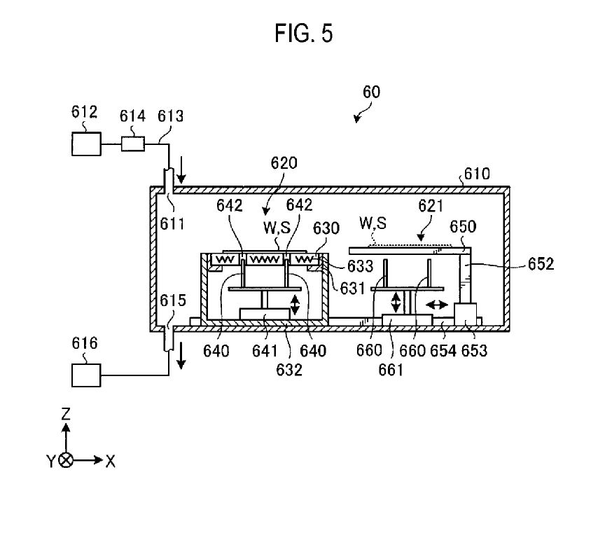

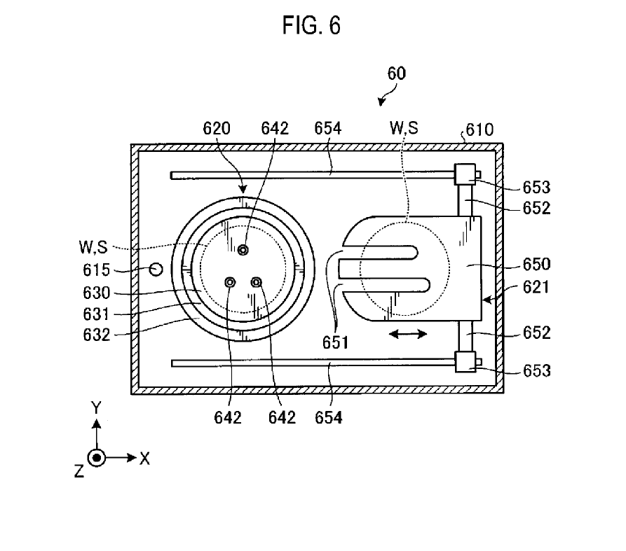

Next, a configuration of the heat treatment apparatus 60 will be described with reference to FIGS. 5 and 6. FIG. 5 is a schematic side view showing the configuration of the heat treatment apparatus 60. FIG. 6 is a schematic plane view showing the configuration of the heat treatment apparatus 60.

As shown in FIG. 5, the heat treatment apparatus 60 includes a hermetically sealable processing container 610. An inlet/outlet (not shown) is formed in a side surface of the processing container 610, which faces the second transfer zone 30 (see FIG. 1). An opening/closing shutter (not shown) is installed in the inlet/outlet.

A gas supply port 611 through which an inert gas (e.g., nitrogen gas) is supplied into the processing container 610, is formed in a ceiling surface of the processing container 610. The gas supply port 611 is coupled to a gas supply source 612 through a gas supply pipe 613. A gas supply kit 614 including a valve, a flow rate regulator and the like, which control a flow of the inert gas, is installed in the gas supply pipe 613.

A suction port 615 for suctioning an internal atmosphere of the processing container 610 is formed in a bottom surface of the processing container 610. The suction port 615 is connected to a negative pressure generator 616 such as a vacuum pump.

Inside the processing container 610, there are installed a heating unit 620 configured to heat the target substrate W or the support substrate S, and a temperature adjusting unit 621 configured to adjust a temperature of the target substrate W or the support substrate S. The heating unit 620 and the temperature adjusting unit 621 are arranged side by side in the X-axis direction.

The heating unit 620 includes an annular holding member 631 having a heat plate 630 received therein, which holds an peripheral portion of the heat plate 630, and a substantially tubular support ring 632 which surrounds the periphery of the holding member 631. The heat plate 630, which has a substantially disk shape thickness, is configured to heat the target substrate W or the support substrate S loaded thereon. Further, the heat plate 630 incorporates, e.g., heaters 633. A heating temperature of the heat plate 630 is controlled by, e.g., the control unit 5 such that the target substrate W or the support substrate S loaded on the heat plate 630 is heated at a predetermined temperature.

A plurality of (e.g., three) elevating pins 640 which elevates the target substrate W or the support substrate S which is supported from bottom, is installed below the heat plate 630. The elevating pins 640 are movable up and down by a drive unit 641. A plurality of (e.g., three) through-holes 642 which penetrates the heat plate 630 in a thickness direction is formed near the central portion of the heat plate 630. The elevating pins 640 are inserted through the respective through-holes 642 such that they project from the top of the heat plate 630.

The temperature adjusting unit 621 includes a temperature adjusting plate 650. As shown in FIG. 6, the temperature adjusting plate 650 has a substantially flat rectangular shape. An end surface facing the heat plate 630 in the temperature adjusting plate 650 is bent in a circular arc shape. Two slits 651 are formed along the Y-axis direction in the temperature adjusting plate 650. The slits 651 are formed to extend from the end surface to near the central portion of the temperature adjusting plate 650. The silts 651 prevent the temperature adjusting plate 650 from interfering with the elevating pins 640 of the heating unit 620 and a plurality of (e.g., three) elevating pins 660 (which will be described later) of the temperature adjusting unit 621. Further, a temperature adjusting member (not shown), e.g., a Peltier element, is incorporated in the temperature adjusting plate 650. A cooling temperature of the temperature adjusting plate 650 is controlled by, e.g., the control unit 5, such that the target substrate W or the support substrate S loaded on the temperature adjusting plate 650 is cooled down to a predetermined temperature.

As shown in FIG. 5, the temperature adjusting plate 650 is supported by a support arm 652. The support arm 652 is installed in drive units 653. The drive units 653 are installed on rails 654 extending in the X-axis direction. The rails 654 are installed to extend from the temperature adjusting unit 621 to the heating unit 620. The drive units 653 allow the temperature adjusting plate 650 to move between the heating unit 620 and the temperature adjusting unit 621 along the rails 654.

The three elevating pins 660 which elevate the target substrate W supported from the bottom are installed below the temperature adjusting plate 650. The elevating pins 660 can be moved up and down by an elevation drive unit 661. The elevating pins 660 are inserted through the respective slits 651 such that they project from the top of the temperature adjusting plate 650.

If the target substrate W or the support substrate S is transferred into the processing container 610, the elevating pins 660 that were lifted up in advance and in a standby status, receive the target substrate W or the support substrate S that is transferred thereon. Subsequently, the elevating pins 660 are lowered down to load the target substrate W or the support substrate S on the temperature adjusting plate 650.

Thereafter, the temperature adjusting plate 650 moves above the heat plate 630 along the rails 654 by the operation of the drive units 653 such that the target substrate W or the support substrate S is transferred on the elevating pins 640 which were lifted up in advance and in a standby status. Subsequently, the elevating pins 640 are lowered down to load the target substrate W or the support substrate S on the heat plate 630. Then, the target substrate W or the support substrate S which is loaded on the heat plate 630, is heated to a predetermined temperature.

Thereafter, the elevating pins 640 move upward and the temperature adjusting plate 650 moves above the heat plate 630. Subsequently, the target substrate W or the support substrate S is transferred from the elevating pins 640 to the temperature adjusting plate 650, and the temperature adjusting plate 650 moves toward the second transfer zone 30. During the movement of the temperature adjusting plate 650, a temperature of the target substrate W or the support substrate S is controlled to a predetermined temperature.

<5. Configuration of Edge Cut Apparatus>

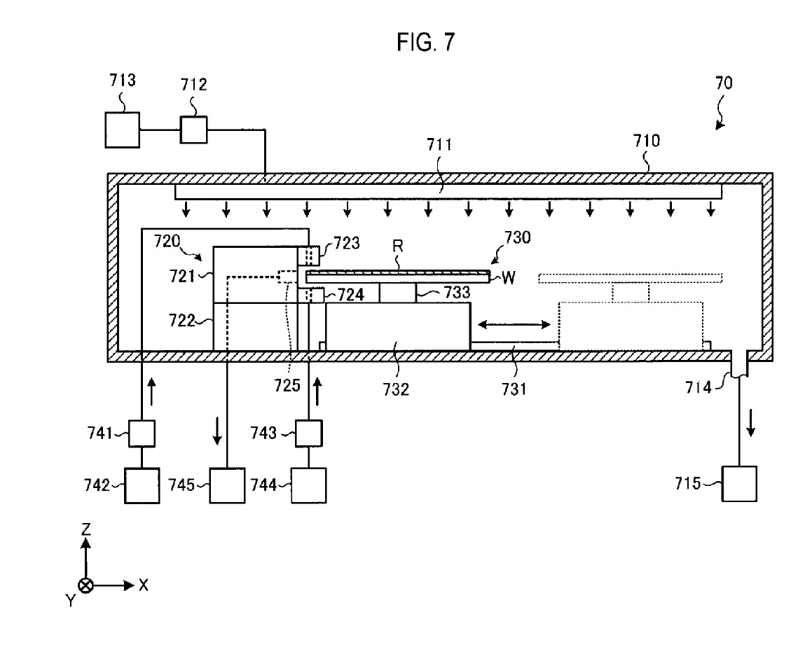

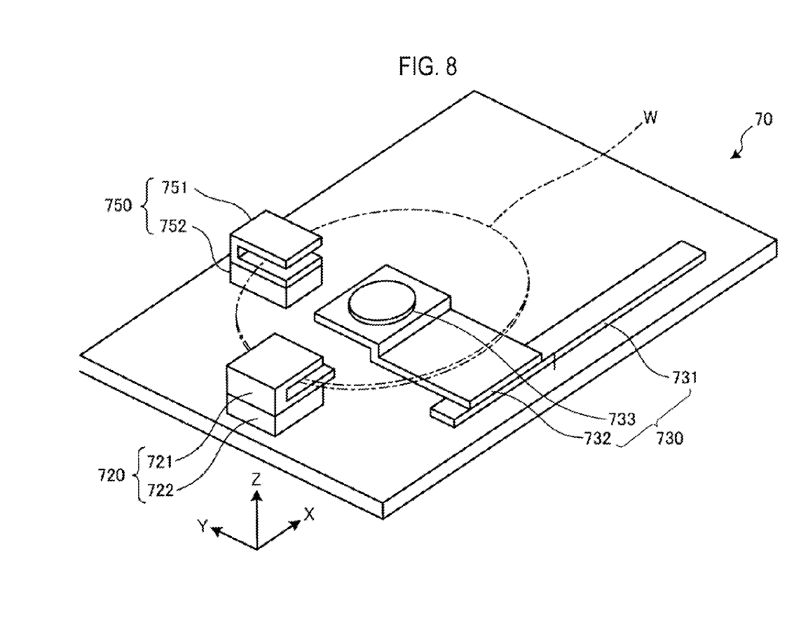

Next, a configuration of the edge cut apparatus 70 will be described with reference to FIGS. 7 and 8. FIG. 7 is a schematic side view showing the configuration of the edge cut apparatus 70. FIG. 8 is a schematic perspective view of the configuration of the edge cut apparatus 70.

As shown in FIG. 7, the edge cut apparatus 70 includes a hermetically sealable processing container 710. An inlet/outlet (not shown) through which the target substrate W is transferred, is formed in a side surface facing the second transfer zone 30 in the processing container 710 (see FIG. 1). An opening/closing shutter (not shown) is installed in the inlet/outlet.

An FFU (Fan Filter Unit) 711 is installed in a ceiling of the processing container 710. The FFU 711 is provided to form a down flow within the processing container 710. The FFU 711 is coupled to a gas supply source 713 through a supply kit 712 which includes a valve, a flow rate regulator and the like. A suction port 714 for suctioning an internal atmosphere of the processing container 710 is formed in a bottom surface of the processing container 710. The suction port 714 is connected to a negative pressure generator 715 such as a vacuum pump.

A solvent supply unit 720 and an adsorptive movement unit 730 are installed within the processing container 710. The solvent supply unit 720 is installed at the backward side of the processing container 710 in the X-axis direction. The adsorptive movement unit 730 is installed the forward side of the processing container 710 in the X-axis positive side.

The solvent supply unit 720 includes a main body 721, a base member 722 configured to support the main body 721 at a predetermined height, an upper nozzle 723, a lower nozzle, and a suction member 725. The upper nozzle 723 and the lower nozzle 724 are installed outside the main body 721 and at the backward side of the main body 721 along the X-axis direction. The suction member 725 is installed in the main body 721 and at the forward side of the main body 721 along the X-axis direction.

The upper nozzle 723 and the lower nozzle 724 are installed to face each other at a predetermined vertical interval. The upper nozzle 723 injects an organic solvent such as a thinner downward. The lower nozzle 724 injects the organic solvent upward. The upper nozzle 723 and the lower nozzle 724 are respectively coupled to organic solvent supply sources 742 and 744 through supply kits 741 and 743, each of which includes a valve, a flow rate regulator and the like.

The suction member 725 is installed between the upper nozzle 723 and the lower nozzle 724 and is configured to suck the organic solvent injected from the upper nozzle 723 and the lower nozzle 724. A negative pressure generator 745, e.g., a vacuum pump, is connected to the suction member 725.

The adsorptive movement unit 730 includes a rail 731 extending in the X-axis direction, a moving mechanism 732 which is movable along the rail 731, and an adsorptive holding unit 733 installed on the moving mechanism 732. The adsorptive holding unit 733 adsorptively holds the target substrate W while rotating the target substrate W.

As shown in FIG. 8, the edge cut apparatus 70 further includes an inspection unit 750. The inspection unit 750 is disposed, e.g., at the forward side of the adsorptive holding unit 733 along the Y-axis direction. The inspection unit 750 includes a main body 751 and a base member 752 configured to support the main body 751 at a predetermined height.

The main body 751 of the inspection unit 750 is, e.g., a CCD (Charged Coupled Device) camera which images a surface and a bevel portion of the peripheral portion of the target substrate W or the support substrate S. Specifically, the edge cut apparatus 70 performs the imaging operation using the main body 751 while rotating the adsorptive holding unit 733. Thus, the surface and the bevel portion of the peripheral portion of each of the target substrate W and the support substrate S are imaged over the entire circumference. Image data obtained thus are transmitted to the control unit 5.

Once the target substrate W is carried into the processing container 710, the adsorptive holding unit 733 adsorptively holds the target substrate W loaded thereon. Subsequently, the moving mechanism 732 moves along the rail 731 as indicated by an arrow in FIG. 7 such that the peripheral portion of the target substrate W is located within the inspection unit 750.

Thereafter, the adsorptive holding unit 733 rotates the target substrate W at a low speed, and the main body 751 images the peripheral portion of the target substrate W under rotation. Based on an image data obtained at the body portion 751, the control unit 5 detects an end surface (i.e., tip of the bevel portion) of the target substrate W.

Subsequently, if it is determined that the end surface of the target substrate W is detected, the control unit 5 controls the moving mechanism 732 to move along the rail 731 such that the peripheral portion of the target substrate W is located between the upper nozzle 723 and the lower nozzle 724.

Thereafter, the adsorptive holding unit 733 rotates the target substrate W while the solvent supply unit 720 injects the organic solvent toward the peripheral portion of the target substrate W using both the upper nozzle 723 and the lower nozzle 724. Thus, the release agent R coated on the peripheral portion of the target substrate W is dissolved by the organic solvent, thereby being removed from the target substrate W. The organic solvent injected (or discharged) from the upper nozzle 723 and the lower nozzle 724 is sucked by the suction member 725.

In some cases, the target substrate W may be held by (or loaded on) the adsorptive holding unit 733 in a state where the center of the adsorptive holding unit 733 and the center of the target substrate W are not aligned with each other. As such, if an edge cut process is performed on the target substrate W without detecting such a misalignment state, an amount of the release agent R which is removed from the peripheral portion of the target substrate W may vary depending on positions at which the target substrate W rotates.

However, the edge cut apparatus 70 according to the first embodiment detects the end surface of the target substrate W in advance, thus accurately sensing the positions of the end surface of the target substrate W even if the rotation is performed at any position. That is to say, the edge cut apparatus 70 rotates the target substrate W while properly moving the adsorptive holding unit 733 in the horizontal direction, with the solvent supply unit 720 located at a fixed place. With this configuration, it is possible to uniformly control the removal amount of the release agent R from the peripheral portion of the target substrate W.

Further, the edge cut apparatus 70 according to the first embodiment may perform inspecting a surface state of the support substrate S or the target substrate W (which has been subjected to the edge cut process) using the inspection unit 750. This will be described later.

<6. Configuration of Bonding Apparatus>

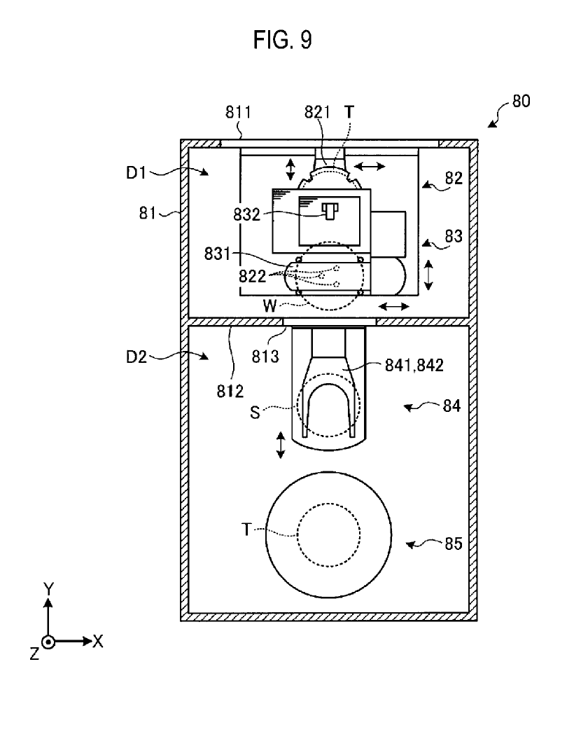

Next, a configuration of the bonding apparatus 80 will be described with reference to FIG. 9. FIG. 9 is a schematic plane view showing the configuration of the bonding apparatus 80.

As shown in FIG. 9, the bonding apparatus 80 includes a hermetically sealable processing chamber 81. An inlet/outlet 811 through which the target substrate W, the support substrate S and the laminated substrate T is transferred, is formed at a side surface facing the second transfer zone 30 in the processing chamber 81. An opening/closing shutter (not shown) is installed in the inlet/outlet 811.

The processing chamber 81 includes an internal wall 812 by which the interior of the processing container 81 is partitioned into a pretreatment zone D1 and a bonding zone D2. The internal wall 812 includes an inlet/outlet 813 through which the target substrate W, the support substrate S and the laminated substrate T is transferred. An opening/closing shutter (not shown) is installed in the inlet/outlet 813. The inlet/outlet 811 is formed in a side of the pretreatment zone D1 in the processing container 81.

In the pretreatment zone D1, there is installed a delivery unit 82 which delivers the target substrate W, the support substrate S and the laminated substrate T between the bonding apparatus 80 and the outside. The delivery unit 82 is disposed adjacent to the inlet/outlet 811.

The delivery unit 82 includes a delivery arm 821 and a plurality of support pins 822. The delivery arm 821 is configured to deliver the target substrate W, the support substrate S and the laminated substrate T between the second transfer device 31 (see FIG. 1) and the support pins 822. The plurality of (e.g., three) support pins 822 support the target substrate W, the support substrate S and the laminated substrate T.

In some embodiments, the delivery unit 82 may be provided in multiple stages (e.g., two stages) in the vertical direction such that two of the target substrate W, the support substrate S and the laminated substrate T are simultaneously transferred. As an example, the delivery unit 82 of one stage may be used in transferring the target substrate W or the support substrate S before bonding, while the delivery unit 82 of the other stage may be used in transferring the laminated substrate T after bonding. Alternatively, the delivery unit 82 of one stage may be used in transferring the target substrate W before bonding, while the delivery unit 82 of the other stage may be used in transferring the support substrate S before bonding.

An inverting unit 83 configured to invert front and rear surfaces of the target substrate W for example, is installed at the backward side of the Y-axis direction in the pretreatment zone D1, i.e., a position facing the inlet/outlet 813.

The inverting unit 83 includes a holding arm 831 which holds the target substrate W or the support substrate S while inserting the target substrate W or the support substrate S thereinto. The holding arm 831 is configured to extend in the horizontal direction (in the X-axis direction in FIG. 9). Further, the holding arm 831 is rotatable about a horizontal axis and is movable in the horizontal direction (the X-axis and Y-axis directions) and in the vertical direction (the Z-axis direction).

The inverting unit 83 includes a position adjusting mechanism configured to adjust a horizontal orientation of the target substrate W or the support substrate S. The position adjusting mechanism includes a detection unit 832 configured to detect a position of a notch formed in the support substrate S or the target substrate W. The inverting unit 83 allows the detection unit 832 to detect the position of the notch while horizontally moving the support substrate S or the target substrate W that is held by the holding arm 831, thereby adjusting the position of the notch. Thus, the horizontal orientation of the target substrate W or the support substrate S is adjusted.

At the forward side of the Y-axis direction in the bonding zone D2, a transfer unit 84 is disposed to transfer the target substrate W, the support substrate S and the laminated substrate T between the delivery unit 82, the inverting unit 83 and a bonding unit 85 (which will be described later). The transfer unit 84 is disposed adjacent to the inlet/outlet 813.

The transfer unit 84 includes two transfer arms 841 and 842. The transfer arms 841 and 842 are disposed in two stages in that order from the bottom, and are moved in horizontal and vertical directions by a drive unit (not shown).

The transfer arm 841 holds and transfers, for example, the rear surface (i.e., the non-bonding surface Sn) of the support substrate S. The transfer arm 842 transfers the target substrate W while holding the peripheral portion of the front surface (i.e., the bonding surface Wj) of the target substrate W whose front and rear surfaces are inverted by the inverting unit 83.

At the backward side of the Y-axis direction in the bonding zone D2, the bonding unit 85 is disposed to bond the target substrate W and the support substrate S together.

In the bonding apparatus 80 configured as above, if the target substrate W is transferred to the delivery arm 821 of the delivery unit 82 by the second transfer device 31 (see FIG. 1), the delivery arm 821 delivers the target substrate W on the support pins 822. Thereafter, the target substrate W is transferred from the support pins 822 to the inverting unit 83 by the transfer arm 841 of the transfer unit 84.

Upon the transfer of the target substrate W to the inverting unit 83, the position of the notch formed in the target substrate W is detected by the detection unit 832 of the inverting unit 83 such that the horizontal orientation of the target substrate W is adjusted. Thereafter, the front and rear surfaces of the target substrate W are inverted by the inverting unit 83. That is to say, the bonding surface Wj is oriented downward.

Thereafter, the target substrate W is transferred from the inverting unit 83 to the bonding unit 85 by the transfer arm 842 of the transfer unit 84. At this time, the transfer arm 842 holds the peripheral portion of the target substrate W, which makes it possible to prevent the bonding surface Wj from being contaminated by, e.g., particles adhering to the transfer arm 842.

On the other hand, if the support substrate S held by the second transfer device 31 (see FIG. 1) is transferred to the delivery arm 821 of the delivery unit 82, the delivery arm 821 delivers the support substrate S on the support pins 822. Thereafter, the support substrate S is transferred from the support pins 822 to the inverting unit 83 by the transfer arm 841 of the transfer unit 84.

Upon the transfer of the support substrate S into the inverting unit 83, the position of the notch formed in the support substrate S is detected by the detection unit 832 of the inverting unit 83 such that the horizontal orientation of the support substrate S is adjusted. Thereafter, the support substrate S is transferred from the inverting unit 83 to the bonding unit 85 by the transfer arm 841 of the transfer unit 84.

Upon completion of transferring the target substrate W and the support substrate S into the bonding unit 85, the target substrate W and the support substrate S are bonded by the bonding unit 85, thus forming the laminated substrate T. The laminated substrate T thus formed is transferred from the bonding unit 85 to the delivery unit 82 by the transfer arm 841 of the transfer unit 84, followed by being delivered to the delivery arm 821 through the support pins 822, followed by being delivered from the delivery arm 821 to the second transfer device 31.

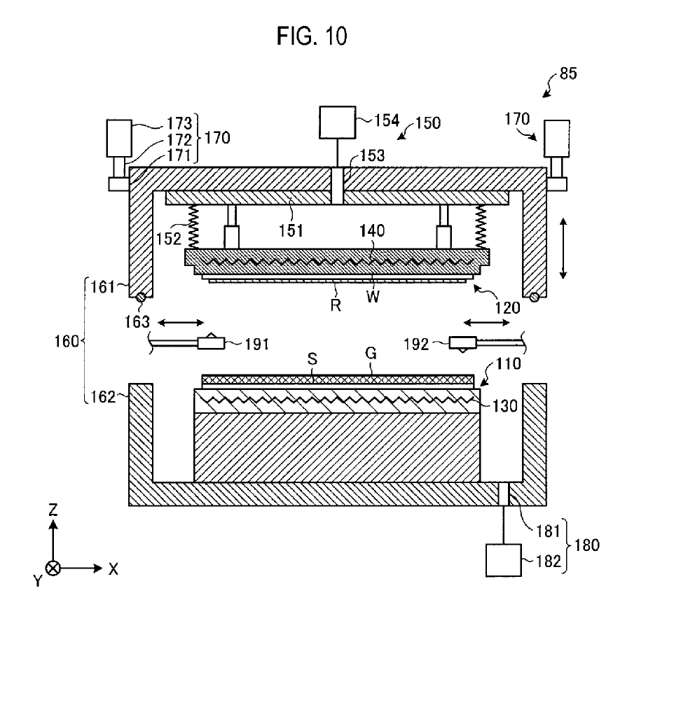

Next, a configuration of the bonding unit 85 will be described with reference to FIG. 10. FIG. 10 is a schematic side view showing the configuration of the bonding unit 85.

As shown in FIG. 10, the bonding unit 85 includes a first holding unit 110 and a second holding unit 120 disposed above the first holding unit 110 while facing the first holding unit 110.

The first holding unit 110 and the second holding unit 120 are, e.g., electrostatic chucks, and are configured to hold the support substrate S and the target substrate W by electrostatically adsorbing them, respectively. The first holding unit 110 holds the support substrate S from below and the second holding unit 120 holds the target substrate W from above. The support substrate S and the target substrate W are respectively held by the first holding unit 110 and the second holding unit 120 in a state where the bonding surfaces Sj and Wj thereof face each other.

In some embodiments, each of the first holding unit 110 and the second holding unit 120 may include a vacuum adsorbing unit configured to vacuum-adsorb the support substrate S and the target substrate W, in addition to an electrostatic adsorbing unit configured to electrostatically adsorb the support substrate S and the target substrate W.

Further, the bonding unit 85 includes a first heating mechanism 130, a second heating mechanism 140 and a pressing mechanism 150.

The first heating mechanism 130 is built in the first holding unit 110. The first heating mechanism 130 heats the first holding unit 110 such that the support substrate S held by the first holding unit 110 is kept at a predetermined temperature. Similarly, the second heating mechanism 140 is built in the second holding unit 120. The second heating mechanism 140 heats the second holding unit 120 such that the target substrate W held by the second holding unit 120 is kept at a predetermined temperature.

The pressing mechanism 150 moves the second holding unit 120 vertically downward such that the target substrate W is brought into contact with the support substrate S, thereby pressing the target substrate W against the support substrate S. The pressing mechanism 150 includes a base member 151, a pressurizing vessel 152, a gas supply pipe 153, and a gas supply source 154. The base member 151 is installed on an internal surface of a ceiling of a first chamber part 161, which will be described below.

The pressurizing vessel 152 is formed of, e.g., bellows made of stainless steel, which can be vertically expanded/contracted. The pressurizing vessel 152 has a lower end portion which is fixed to an upper surface of the second holding unit 120, and an upper end portion which is fixed to a lower surface of the base member 151.

The gas supply pipe 153 has one end connected to the pressurizing vessel 152 through the base member 151 and the first chamber part 161 (which will be described later), and the other end connected to the gas supply source 154.

A gas is supplied from the gas supply source 154 into the pressurizing vessel 152 via the gas supply pipe 153, thus expanding the pressurizing vessel 152. This moves the second holding unit 120 downward. Thus, the target substrate W is brought into contact with the support substrate S and is pressed against the support substrate S. A pressing force applied to the target substrate W and the support substrate S is controlled by regulating a pressure of the gas supplied into the pressurizing vessel 152.

Further, the bonding unit 85 includes a chamber 160, moving mechanisms 170, a depressurizing unit 180, a first imaging unit 191, and a second imaging unit 192.

The chamber 160 is a hermetically-sealable processing container and includes the first chamber part 161 and a second chamber part 162. The first chamber part 161 is a cylindrical container having a ceiling with a bottom portion opened. The first chamber part 161 accommodates the second holding unit 120 and the pressurizing vessel 152. The second chamber part 162 is a cylindrical container having a bottom with an upper portion opened. The second chamber part 162 accommodates the first holding unit 110 and the like.

The first chamber part 161 is vertically movable by an elevation mechanism (not shown) such as an air cylinder. By such an elevation mechanism, the first chamber part 161 moves downward to bring into contact with the second chamber part 162, thus forming a closed space inside the chamber 160. A seal member 163 for securing an air tightness of the chamber 160 is installed in a surface where the first chamber part 161 is brought into contact with the second chamber part 162. Examples of the seal member 163 may be an O-ring.

The moving mechanisms 170 are installed in a peripheral portion of the first chamber part 161. The moving mechanisms 170 horizontally move the first chamber part 161, thereby horizontally moving the second holding unit 120 accommodated in the first chamber part 161. The moving mechanisms 170 may be installed at, e.g., five positions, in the peripheral portion of the first chamber part 161. Four of the moving mechanisms 170 may be used in horizontally moving the second holding unit 120 and the remaining one may be used in rotating the second holding unit 120 about a vertical axis.

Each of the moving mechanisms 170 includes a cam 171 configured to move the second holding unit 120 by contacting with the peripheral portion of the first chamber part 161, and a rotation drive unit 173 configured to rotate the cam 171 through a shaft 172. The cam 171 is installed to be eccentric from the center axis of the shaft 172. By rotating the cam 171 with the rotation drive unit 173, the center position of the cam 171 to the second holding unit 120 moves so that the second holding unit 120 can be horizontally moved.

The depressurizing unit 180 is installed, for example, below the second chamber part 162 and is configured to reduce an internal pressure of the chamber 160. The depressurizing unit 180 includes a suction pipe 181 for sucking the internal atmosphere of the chamber 160, and a suction device 182 (e.g., a vacuum pump) connected to the suction pipe 181.

The first imaging unit 191 is disposed below the second holding unit 120 to image the surface of the target substrate W held by the second holding unit 120. The second imaging unit 192 is disposed above the first holding unit 110 to image the surface of the support substrate S held by the first holding unit 110.

The first imaging unit 191 and the second imaging unit 192 are configured such that they can be horizontally moved by respective moving mechanisms (not shown). Before moving the first chamber part 161 downward, the first imaging unit 191 and the second imaging unit 192 move into the chamber 160 to image the surfaces of the target substrate W and the support substrate S. Image data obtained at the first imaging unit 191 and the second imaging unit 192 is transmitted to the control unit 5. For example, a wide angle type of CCD camera may be used as the first imaging unit 191 and the second imaging unit 192.

<Specific Operation of Bonding System>

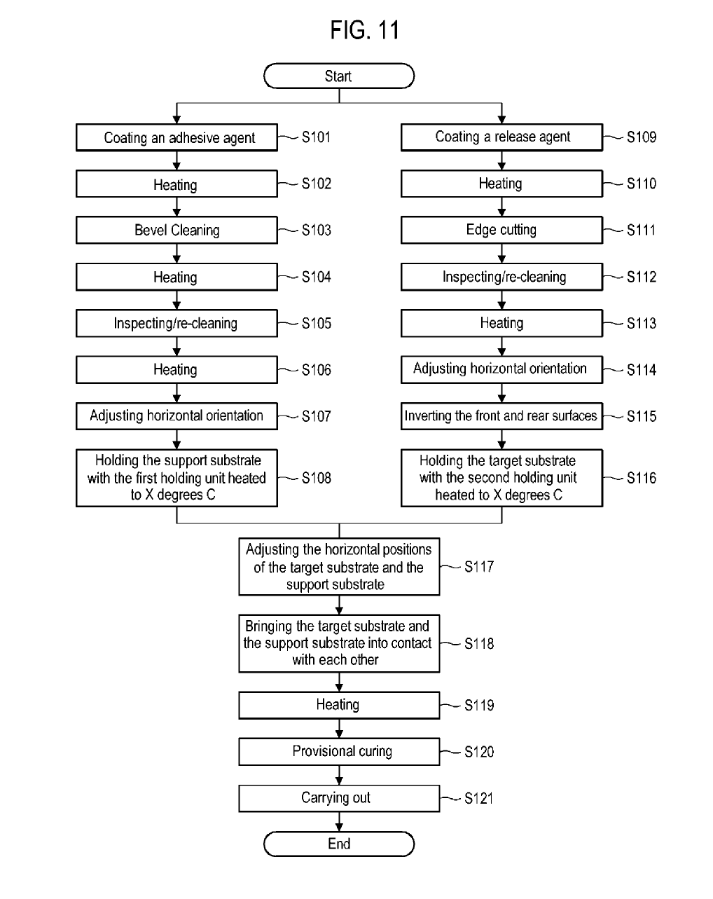

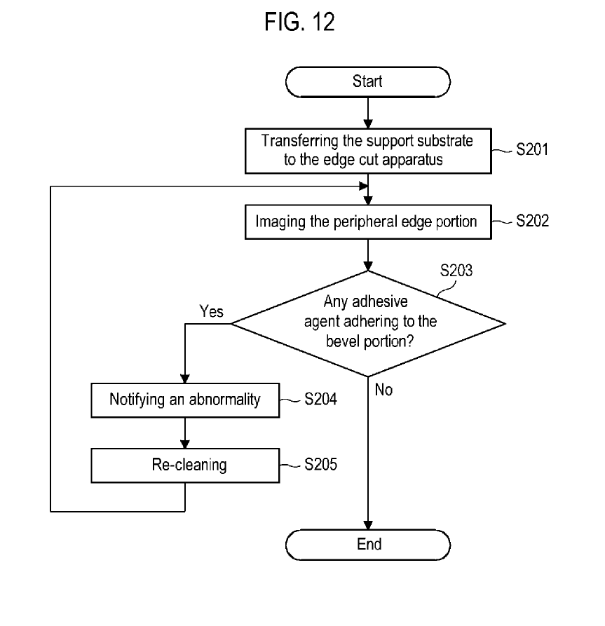

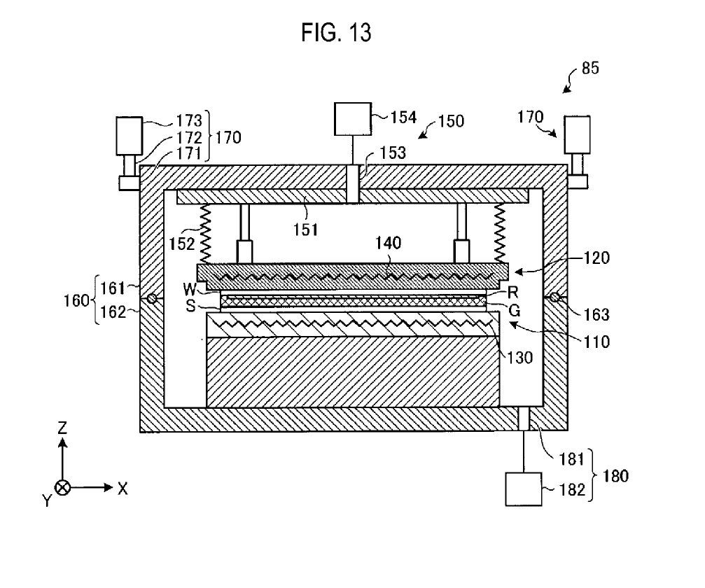

Next, a sequence of bonding processes implemented by the bonding system 1 according to the first embodiment will be described with reference to FIGS. 11 to 13. FIG. 11 is a flowchart showing a sequence of the entire process implemented by the bonding system 1 according to the first embodiment. FIG. 12 is a flowchart showing a sequence of an inspecting/recleaning process. FIG. 13 is a view showing an exemplary operation of the bonding process. Each process shown in FIG. 11 is performed by respective apparatuses of the bonding system 1 under the control of the control device 4.

First, in the bonding system 1, a cassette Cw with a plurality of target substrates W accommodated therein, a cassette Cs with a plurality of support substrates S accommodated therein, and an empty cassette Ct are loaded on the respective loading parts 12 of the carry-in/carry-out station 2. Thereafter, the first transfer device 14 takes out a support substrate S from the cassette Cs and transfers the same to the first delivery unit 20 of the processing station 3. At this time, the support substrate S is transferred with the non-bonding surface Sn thereof oriented downward.

The support substrate S transferred to the first delivery unit 20 is picked up by the second transfer device 31 and subsequently, is transferred to the first coating apparatus 40.

In the first coating apparatus 40, a process of coating the bonding surface Sj of the support substrate S with an bonding agent G is performed by the bonding agent injection part 431 (in Step S101). Thus, a coating film of the bonding agent G is formed on the bonding surface Sj of the support substrate S.

Subsequently, the support substrate S inside the first coating apparatus 40 is picked up by the second transfer device 31 and is transferred to the heat treatment apparatus 60.

In the heat treatment apparatus 60, a process of heating the support substrate S to a predetermined temperature is performed (in Step S102). Thus, an organic solvent contained in the bonding agent G coated on the support substrate S is vaporized. Thereafter, the support substrate S is cooled down to a predetermined temperature, e.g., normal temperature, within the heat treatment apparatus 60. The bonding agent G, from which the organic solvent is vaporized, becomes hard so that the bonding agent G does not flow down even when the support substrate S is tilted.

Subsequently, the support substrate S inside the heat treatment apparatus 60 is picked up by the second transfer device 31 and is transferred to the second coating apparatus 50.

In the second coating apparatus 50, a process of cleaning a bevel portion of the support substrate S is performed by the bevel cleaning unit 55 (in Step S103). Thus, the bonding agent G adhering to the bevel portion of the support substrate S is removed.

Subsequently, the support substrate S inside the second coating apparatus 50 is picked up by the second transfer device 31 and is transferred to the heat treatment apparatus 60.

In the heat treatment apparatus 60, a process of heating the support substrate S to a predetermined temperature is performed (in Step S104). This heating process vaporizes the organic solvent adhered to the support substrate S during the bevel cleaning process (in Step S103), thus removing the organic solvent from the support substrate S.

Subsequently, the bonding system 1 performs an inspecting/recleaning process (Step S105). The inspecting/recleaning process is to inspect the bevel portion of the support substrate S subjected to the bevel cleaning process, and again clean the bevel portion if it is determined that the bonding agent G remains in the bevel portion. This inspecting/recleaning process will be described with reference to FIG. 12.

As shown in FIG. 12, at the start of the inspecting/recleaning process, the second transfer device 31 takes out the support substrate S from the heat treatment apparatus 60 and transfers the same to the edge cut apparatus 70 (in Step S201).

Subsequently, the edge cut apparatus 70 rotates the support substrate S using the adsorptive holding unit 733 and simultaneously, captures an image of the peripheral portion (i.e., a surface of the peripheral portion and the bevel portion) of the support substrate S using the inspection unit 750 (in Step S202). The inspection unit 750 transmits an image data of the captured image to the control unit 5.

Subsequently, based on the image data provided from the inspection unit 750, the control unit 5 determines whether the bonding agent G adheres to the bevel portion of the support substrate S (in Step S203). As an example, if a degree of irregularity of a region corresponding to the bevel portion of the support substrate S in the captured image exceeds a predetermined threshold value, the control unit 5 determines that the bonding agent G adheres to the bevel portion of the support substrate S. Alternatively, an initial image data of the bevel portion of the support substrate S before the coating of the bonding agent G may be previously stored in the storage unit 6. With this configuration, when a degree of coincidence between the initial image data stored in the storage unit 6 and the image data obtained at the inspection unit 750 exceeds a threshold value, the control unit 5 may determine that the bonding agent G adheres to the bevel portion of the of the support substrate S.

If it is determined at Step S203 that the bonding agent G adheres to the bevel portion of the support substrate S (“YES” at Step S203), the control unit 5 performs a process of notifying an abnormality (in Step S204).

As an example, the control unit 5 may turn on an indication lamp (not shown) of the bonding system 1. Then, the control unit 5 notifies a host device of the information which indicates that the abnormality has occurred in the chemical solution supply source 552 coupled to the bevel cleaning unit 55 of the second coating apparatus 50. In some embodiments, the control unit 5 may display the information on a display unit (not shown) of the bonding system 1.

When the bonding agent G remains in the bevel portion of the support substrate S, an amount of the chemical solution which is injected from the bevel cleaning unit 55 of the second coating apparatus 50 may sometimes not reach a prescribed amount, which makes it difficult to sufficiently spread the chemical solution to the rear surface of the support substrate S. To address such concerns, if it is determined that the bonding agent G remains in the bevel portion of the support substrate S, the control unit 5 notifies the host device of the information which indicates that the abnormality has occurred in the chemical solution supply source 552. This enables a worker to rapidly specify the occurrence of the abnormality and the cause thereof

Subsequently, the edge cut apparatus 70 performs a process of recleaning the bevel portion of the support substrate S (in Step S205). Specifically, the edge cut apparatus 70 rotates the support substrate S using the adsorptive holding unit 733 and simultaneously, injects an organic solvent (used as a chemical solution) onto front and rear surfaces near the peripheral portion of the support substrate S, including the bevel portion, using the solvent supply unit 720 (used as a chemical solution injection unit), such that the organic solvent flows toward the peripheral portion of the support substrate S. Thus, the bonding agent G remaining in the bevel portion of the support substrate S is removed.

Upon completion of the recleaning process of Step S205, the control unit 5 controls the edge cut apparatus 70 to perform the operation of Step S202 where the peripheral portion of the support substrate S is inspected again. The edge cut apparatus 70 repeats a sequence of Steps S202 to S205 until it is determined at Step S203 that the bonding agent G does not adhere to the bevel portion of the support substrate S. If the result of the determination at Step S203 is NO, the inspecting/recleaning process is terminated.

Upon termination of the inspecting/recleaning process, the support substrate S inside the edge cut apparatus 70 is picked up by the second transfer device 31 and is transferred to the heat treatment apparatus 60.

The heat treatment apparatus 60 heats the support substrate S transferred thereto to a predetermined temperature (in Step S106). The heating process of Step S106 is performed at a higher temperature than those of the heating processes at Steps S102 and S104. Specifically, the heat treatment apparatus 60 heats the support substrate S to a temperature which is higher than the normal temperature but lower than a softening temperature (120 to 140 degrees C.) of the bonding agent G.

By virtue of the heating process of Step S106, the organic solvent which could not be completely removed in the heating processes of Steps S102 and S104 is vaporized, thus further hardening the bonding agent G. Further, the organic solvent adhered to the support substrate S in the inspecting/recleaning process of Step S105 is vaporized and removed from the support substrate S.

Subsequently, the support substrate S inside the heat treatment apparatus 60 is picked up by the second transfer device 31 and is transferred to the bonding apparatus 80.

The horizontal orientation of the support substrate S transferred to the bonding apparatus 80 is adjusted by the inverting unit 83 (in Step S107). Specifically, the inverting unit 83 detects a position of a notch formed in the support substrate S using the detection unit 832, while horizontally moving the support substrate S held by the holding arm 831, thereby adjusting the position of the notch. In this way, the horizontal orientation of the support substrate S is adjusted.

In some cases, even if the bonding agent G adhering to the bevel portion of the support substrate S has not been completely removed in the bevel cleaning process (in Step S103), the horizontal orientation adjustment process of Step S107 may be performed with the bonding agent G adhered to the notch of the support substrate S. This may cause that, at Step S107, the bonding apparatus 80 fails to detect the position of the notch, or erroneously detects the position of the notch. This makes it impossible to appropriately adjust the horizontal orientation of the support substrate S.

However, according to the bonding system 1 of the first embodiment, the surface state of the bevel portion of the support substrate S is inspected in the inspecting/recleaning process (Step S105). Thus, if it is determined that the bonding agent G remains in the bevel portion, the recleaning process of the bevel portion is performed. This avoids failure of the detection of the position of the notch or the erroneous detection of the position of the notch, thus properly performing the adjustment of the horizontal orientation of the support substrate S.

Subsequently, the support substrate S is held by the first holding unit 110 which is preheated to X degrees C., i.e., the softening temperature (120 to 140 degrees C.) of the bonding agent G, by the first heating mechanism 130 (in Step S108). This softens the bonding agent G coated on the support substrate S.

The heating temperature of the first heating mechanism 130 may be a temperature which is closer to the softening temperature (120 to 140 degrees C.) of the bonding agent G than the normal temperature (about 20 degrees C.) and the hardening temperature (about 180 degrees C.) of the bonding agent G. The support substrate S is held by the first holding unit 110 with the bonding surface Sj thereof oriented upward.

In the meantime, the target substrate W is processed in parallel with the processes of Step S101 to S108.

Similarly, the target substrate W received in the cassette Cw is picked up by the first transfer device 14 and is transferred to the first delivery unit 20 of the processing station 3. At this time, the target substrate W is transferred with the non-bonding surface Wn thereof oriented downward.

The target substrate W transferred to the first delivery unit 20 is picked up by the second transfer device 31 and is transferred to the second coating apparatus 50.

In the second coating apparatus 50, a process of coating a release agent R on the bonding surface Wj of the target substrate W is performed by the release agent injection part 531 (in Step S109). Thus, a coating film of the release agent R is formed on the bonding surface Wj of the target substrate W.

Subsequently, the target substrate W inside the second coating apparatus 50 is picked up by the second transfer device 31 and is transferred to the heat treatment apparatus 60.

In the heat treatment apparatus 60, a process of heating the target substrate W to a predetermined temperature is performed (in Step S110). Thus, an organic solvent contained in the release agent R coated on the target substrate W is vaporized. Thereafter, the target substrate W is cooled down to a predetermined temperature, e.g., the normal temperature, within the heat treatment apparatus 60. The release agent R, from which the organic solvent is vaporized, becomes hard so that the release agent R does not flow down even when the target substrate W is tilted.

Subsequently, the support substrate S inside the heat treatment apparatus 60 is picked up by the second transfer device 31 and is transferred to the edge cut apparatus 70.

In the edge cut apparatus 70, an edge cut process of removing the release agent R from the peripheral portion of the target substrate W including the bevel portion is performed using the solvent supply unit 720 (in Step S111). Thus, the release agent R is removed from the peripheral portion of the target substrate W including the bevel portion so that the uncoated region Q (see FIG. 2) is formed in the peripheral portion of the bonding surface Wj of the target substrate W.

Subsequently, an inspecting/recleaning process is performed with respect to the target substrate W which has been subjected to the edge cut process (Step S112).

The inspecting/recleaning process of Step S112 is similar to that of Step S105. That is to say, the edge cut apparatus 70 captures images of a surface of the peripheral portion and the bevel portion of the target substrate W using the inspection unit 750. Based on the captured images, the control unit 5 determines whether the release agent R adheres to the bevel portion of the target substrate W. If the control unit 5 determines that the release agent R adheres to the bevel portion of the target substrate W, it controls the edge cut apparatus 70 to reclean the bevel portion of the target substrate W using the solvent supply unit 720.

Subsequently, the target substrate W inside the edge cut apparatus 70 is picked up by the second transfer device 31 and is transferred to the heat treatment apparatus 60.

In the heat treatment apparatus 60, a process of heating the target substrate W to a predetermined temperature is performed (in Step S113). The heating process of Step S113 is performed at a higher temperature than the heating process of Step S110.

This heating process vaporizes the organic solvent (which is not removed in the heating process of Step S110) remaining in the release agent R such that the release agent R is further hardened. Furthermore, the organic solvent adhered to the target substrate W during the inspecting/recleaning process of Step S112 is vaporized and removed from the target substrate W.

As described above, the target substrate W is subjected to the heating process after the edge cut process and the inspecting/recleaning process so that the organic solvent adhering thereto is removed, which makes it possible to prevent voids from generating in the release agent R.

Subsequently, the target substrate W inside the heat treatment apparatus 60 is picked up by the second transfer device 31 and is transferred to the bonding apparatus 80.

The horizontal orientation of the target substrate W transferred to the bonding apparatus 80 is adjusted by the inverting unit 83 (in Step S114).

In the bonding system 1, the surface state of the bevel portion of the target substrate W is inspected in the inspecting/recleaning process (Step S112). If the release agent R remains in the bevel portion, the bevel portion is recleaned. This avoids failure of the detection of the position of the notch or the erroneous detection of the position of the notch, thus properly adjusting the horizontal orientation of the target substrate W.

Subsequently, the front and rear surfaces of the target substrate W are inverted by the inverting unit 83 (in Step S115). Thus, the bonding surface Wj of the target substrate W is oriented downward.

Then, the target substrate W is held by the second holding unit 120 which is preheated to X degrees C. by the second heating mechanism 140 (in Step S116). The target substrate W is held by the second holding unit 120 with the bonding surface Wj thereof oriented downward.

Subsequently, horizontal positions of the target substrate W and the support substrate S are adjusted (in Step S117). A plurality of predetermined reference points may be formed in the peripheral portions of the target substrate W and the support substrate S. The bonding unit 85 captures images of the peripheral portions of the target substrate W and the support substrate S by horizontally moving each of the first imaging unit 191 and the second imaging unit 192 shown in FIG. 10.

Then, the bonding unit 85 adjusts the horizontal position of the target substrate W using the moving mechanisms 170 such that positions of the reference points included in the image captured by the first imaging unit 191 coincide with positions of the reference points included in the image captured by the second imaging unit 192. Specifically, the horizontal position of the target substrate W is adjusted by rotating the cam 171 with the rotation drive unit 173 and horizontally moving the second holding unit 120 through the first chamber part 161.

Now, it is assumed that, in the bevel cleaning process of Step S103 or the edge cut process of Step S111, the bonding agent G adhering to the bevel portion of the support substrate S or the release agent R adhering to the bevel portion of the target substrate W is not completely removed and is kept adhered to the reference points. This may cause that the bonding apparatus 80 fails to detect or erroneously detects the positions of the reference points in Step S117, which makes it impossible to properly perform the process of Step S117.

According to the bonding system 1 of the first embodiment, the surface states of the bevel portions of the support substrate S and the target substrate W are respectively inspected in the inspecting/recleaning processes of Steps S105 and S112. If it is determined that the bonding agent G or the release agent R remains in the respective bevel portion, the bevel portion is subjected to the recleaning process. This avoids failure of the detection of the reference points or an erroneous detection of the reference points, thus properly performing the process of Step S117.

Subsequently, the bonding unit 85 moves the first imaging unit 191 and the second imaging unit 192 out of the chamber 160, followed by moving the first chamber part 161 downward. Thus, the first chamber part 161 is brought into contact with the second chamber part 162 such that a closed space is formed within the chamber 160. Thereafter, the bonding unit 85 sucks an internal atmosphere of the chamber 160 using the depressurizing unit 180 to reduce an internal pressure of the chamber 160.

Then, the bonding unit 85 moves the second holding unit 120 downward using the pressing mechanism 150 such that the target substrate W and the support substrate S are brought into contact with each other (in Step S118). Furthermore, the bonding unit 85 supplies gas into the pressurizing vessel 152 to set the internal pressure of the pressurizing vessel 152 at a desired pressure, thereby pressing the target substrate W and the support substrate S against each other (in Step S119).

The bonding agent G coated on the bonding surface Sj of the support substrate S is softened by heating and the support substrate S is pressed against the target substrate W at the desired pressure for a period of predetermined time. Thus, the target substrate W and the support substrate S are bonded to form the laminated substrate T (see FIG. 13). At this time, the inside of the chamber 160 is kept at a depressurized atmosphere, thus preventing voids from being generated between the target substrate W and the support substrate S.

Subsequently, a temporary hardening process is performed (in Step S120). The temporary hardening process is to temporarily harden the bonding agent G to the extent that the bonding agent G is not completely hardened, thereby suppressing positions of the target substrate W and the support substrate S from being shifted in a subsequent transfer process or other processes.

The bonding unit 85 increases a heating temperature of the laminated substrate T using the first heating mechanism 130 and the second heating mechanism 140 while keeping the laminated substrate T pressed by the pressing mechanism 150.

Specifically, the first heating mechanism 130 and the second heating mechanism 140 heat the laminated substrate T to a temperature equal to or higher than the hardening temperature (about 180 degrees C.) of the bonding agent G, for example, 200 degrees C. Thus, the bonding agent G begins to harden.

Prior to the bonding agent G being completely hardened, the bonding unit 85 stops the heating processes of the first heating mechanism 130 and the second heating mechanism 140. In some cases, in order to completely harden the bonding agent G which is used in the bonding system 1 according to the first embodiment, the laminated substrate T may be heated at 200 degrees C. for about two hours by an apparatus other than the bonding system 1. However, in the temporary hardening process, the laminated substrate T is heated at 200 degrees C. in a short period of time (about 5 to 10 minutes). With this configuration, the bonding agent G is hardened to the extent that the bonding agent G is not completely hardened. Further, the release agent R has such a property that it is not hardened even when heated. For that reason, the release agent R is not hardened by the temporary hardening process.

As described above, the bonding unit 85 according to the first embodiment heats the laminated substrate T at the temperature equal to or higher than the hardening temperature of the bonding agent G in a period of time shorter than the hardening time of the bonding agent G, thereby hardening the bonding agent G to the extent that the bonding agent G is not completely hardened.

Such a configuration prevents positions of the target substrate W and the support substrate S from being shifted in a subsequent transfer process or other processes, thus improving convenience in handling the laminated substrate T.

Further, the bonding unit 85 heats both the entire surfaces of the support substrate S and the target substrate W in the laminated substrate T, thus uniformly heating the laminated substrate T. Accordingly, as compared with a case where the laminated substrate T is heated from any one side of the support substrate S and the target substrate W, it is possible to suppress the laminated substrate T from being deformed, thus preventing voids from being generated in the bonding agent G or the release agent R due to the deformation of the laminated substrate T.

Further, the bonding unit 85 heats the laminated substrate T while pressing the laminated substrate T using the pressing mechanism 150, which makes it possible to reliably suppress the deformation of the laminated substrate T.

Thereafter, the laminated substrate T is unloaded from the bonding apparatus 80 by the second transfer device 31 and is delivered to the first transfer device 14 via the first delivery unit 20. Subsequently, the laminated substrate T is accommodated within the cassette Ct by the first transfer device 14 (in Step S121). In this way, a series of the bonding processes is completed. As described above, the bonding agent G of the laminated substrate T is temporarily hardened by the temporary hardening process to the extent that the bonding agent G is not completely hardened. This suppresses the positions of the target substrate W and the support substrate S from being shifted during the transfer of the laminated substrate T by the second transfer device 31 or the first transfer device 14.

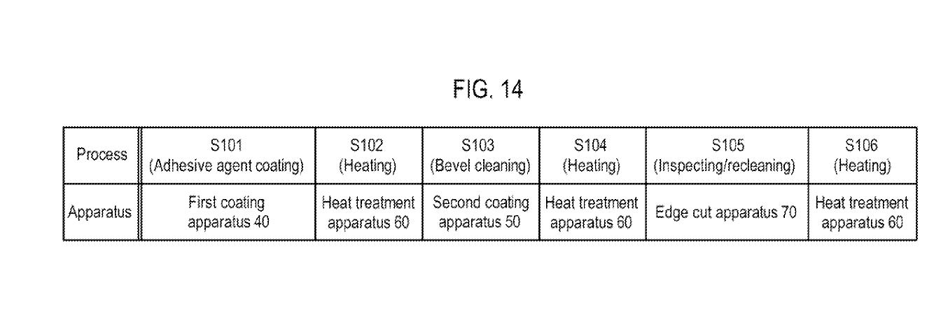

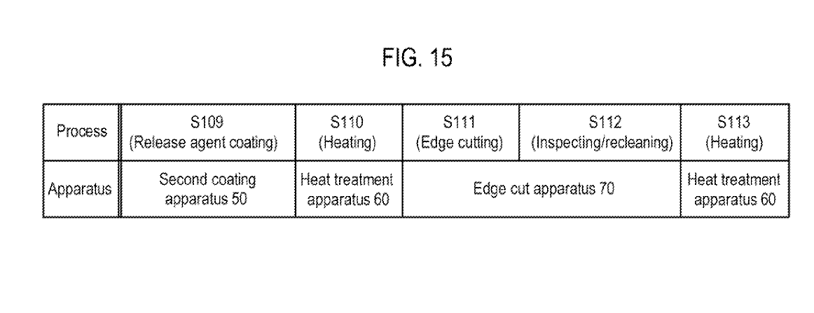

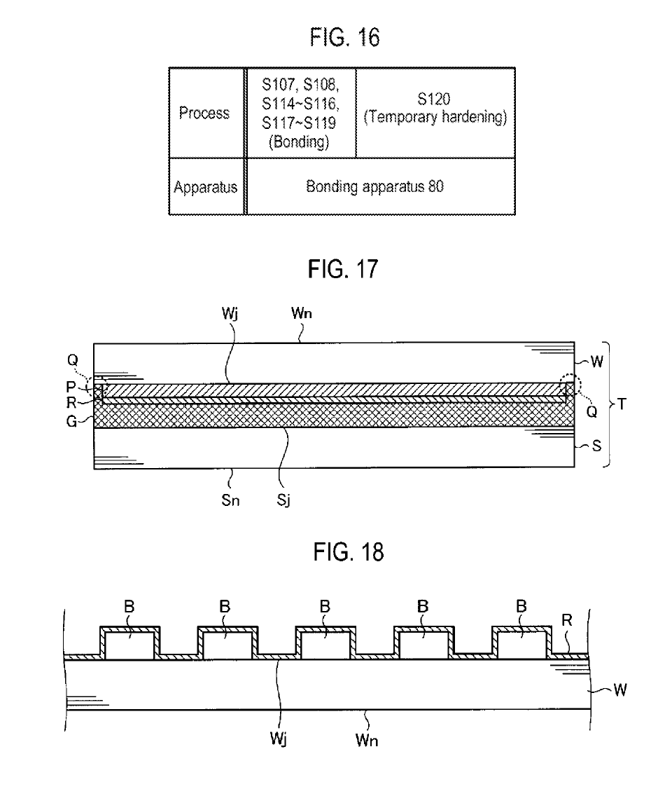

Next, the relationship between each of the processes described above and respective apparatuses configured to perform the processes will be described with reference to FIGS. 14 to 16. FIG. 14 is a view showing each process which are applied to the support substrate S. FIG. 15 is a view showing each process which are applied to the target substrate W. FIG. 16 is view showing the bonding process and the temporary hardening process.

As shown in FIGS. 14 and 15, when processing the support substrate S in the bonding system 1, the process (Step S101) of coating the bonding agent G in Step S101 is performed by the first coating apparatus 40 and the process (Step S103) of cleaning the bevel portion is performed by the second coating apparatus 50. Further, when processing the target substrate W in the bonding system 1, the process (Step S109) of coating the release agent R is performed by the second coating apparatus 50.

As described above, in the bonding system 1, the second coating apparatus 50 configured to perform the bevel cleaning process for the support substrate S is also used in performing the release agent coating process for the target substrate W. That is to say, in the bonding system 1, the bevel cleaning process for the support substrate S and the release agent coating process for the target substrate W are performed by a single coating apparatus. Therefore, according to the bonding system 1, as compared with a case where the aforementioned processes are performed by different coating apparatuses, it is possible to reduce the number of the coating apparatuses.

In the bonding system 1, the bonding agent coating process (Step S101) and the bevel cleaning process (Step S103) for the support substrate S have been described to be performed by different apparatuses.

The bonding agent coating process and the bevel cleaning process may be performed by only the first coating apparatus 40. This prolongs a process time of the first coating apparatus 40. For example, employing only the first coating apparatus 40 causes a delay of a timing at which a subsequent support substrate S is carried into the first coating apparatus 40, resulting in deterioration in throughput. However, according to the bonding system 1, the bonding agent coating process and the bevel cleaning process are performed by different apparatuses, which makes it possible to suppress a reduced throughput, as compared with a case where the bonding agent coating process and the bevel cleaning process are performed by a single apparatus.

As described above, in the bonding system 1, the bonding agent coating process for the support substrate S is performed by the first coating apparatus 40, and the bevel cleaning process for the support substrate S is performed by the second coating apparatus 50 differing from the first coating apparatus 40. Further, the release agent coating process for the target substrate W is performed by the second coating apparatus 50. Therefore, according to the bonding system 1, it is possible to reduce the number of apparatuses while preventing deterioration in throughput.

In the bonding system 1, the heating process (Step S102) is performed after the bonding agent coating process (Step S101), followed by the bevel cleaning process (Step S103). For this reason, even when the bonding agent coating process and the bevel cleaning process are performed by a single apparatus, a process of carrying the support substrate S subjected to the bonding agent coating process out the single apparatus and a process of carrying the support substrate S subjected to the heating process into that apparatus are needed in order to perform a subsequent heating process. Accordingly, even if the bonding agent coating process is performed by the first coating apparatus 40 and the bevel cleaning process is performed by the second coating apparatus 50, it is possible to avoid deterioration in throughput as compared with a case where the processes are performed by the single apparatus.

As described above, in the bonding system 1, the bonding agent coating process for the support substrate S is performed by the first coating apparatus 40, and the release agent coating apparatus for the target substrate W is performed by the second coating apparatus 50.

This configuration enables the bonding system 1 to initiate the release agent coating process for the target substrate W without having to wait for the completion of the bonding agent coating process for the support substrate S. Therefore, according to the bonding system 1, as compared with a case where the bonding agent coating process and the release agent coating process are performed by a single apparatus, it is possible to shorten a period of time required for performing a series of the bonding processes.

Further, as described above, in the bonding system 1, the bevel cleaning process for the support substrate S is performed by the second coating apparatus 50, while the inspecting/recleaning process for the support substrate S is performed by the edge cut apparatus 70 differing from the second coating apparatus 50.

If the bonding agent G remains in the bevel portion of the support substrate S subjected to the bevel cleaning process, there is a possibility that an abnormality has occurred in the bevel cleaning unit 55 of the second coating apparatus 50. As such, even if the bevel portion is recleaned by the bevel cleaning unit 55, the bonding agent G may still remain in the bevel portion.

However, in the bonding system 1, the recleaning of the bevel portion is performed by the edge cut apparatus 70 differing from the second coating apparatus 50 which performs the bevel cleaning process. This makes it possible to reliably remove the bonding agent G remaining in the bevel portion of the support substrate S.

In some embodiments, the first coating apparatus 40 may be provided with a bevel cleaning unit similar to the bevel cleaning unit 55 of the second coating apparatus 50. With this configuration, when the bonding agent G remains in the bevel portion of the support substrate S subjected to the bevel cleaning process, the bonding system 1 can perform the recleaning process using the first coating apparatus 40 instead of the edge cut apparatus 70.

As described above, in the bonding system 1, the edge cut apparatus 70 includes the inspection unit 750 configured to inspect the surface state of the support substrate S or the target substrate W.

With this configuration, after the inspecting process by the inspection unit 750, if it is determined that the surface state of the support substrate S or the target substrate W is abnormal, the recleaning process may be performed in place without transferring the support substrate S or the target substrate W to other apparatuses. This makes it possible to shorten a period of time required for performing the inspecting/recleaning process.

As described above, in the bonding system 1, the heating process for the support substrate S is performed between the bevel cleaning process and the inspecting/recleaning process, thereby removing the chemical solution (or the organic solvent) adhered to the support substrate S in the bevel cleaning process. This configuration eliminates, in the inspecting process, an occurrence of erroneous determination that the bonding agent G remains in the bevel portion, due to the chemical solution remaining in the bevel portion of the support substrate S.

As described above, in the bonding system 1, the heating process (Step S110) is performed between the release agent coating process (Step S109) and the edge cut process (Step S111) for the target substrate W. With this configuration, the organic solvent included in the release agent R coated on the target substrate W is removed to harden the release agent R, which makes it possible to cleanly remove the release agent R from the peripheral portion of the target substrate W in the edge cut process.

As shown in FIG. 16, in the bonding system 1, the temporary hardening process (Step S120) is performed using the bonding apparatus 80 which performs the bonding process (a sequence of Steps S107, S108, S114 to S116 and S117 to S119). With this configuration, after the bonding process by the bonding apparatus 80, the temporary hardening process is performed in place without transferring the laminated substrate T to other apparatuses, which makes it possible to shorten a period of time required for the temporary hardening process. Further, as compared with a case where the temporary hardening process is performed in another apparatus differing from the bonding apparatus 80, there is no need to manage a temperature of the laminated substrate T during the transfer thereof

As described above, the bonding system 1 according to the first embodiment includes the processing station 3 and the carry-in/carry-out station 2. In the processing station 3, specified processes are performed with respect to the support substrate S (corresponding to one example of a “first substrate”) and the target substrate W (corresponding to one example of a “second substrate”). In the carry-in/carry-out station 2, the support substrate S, the target substrate W or the laminated substrate T is carried into and out of the processing station 3. The processing station 3 includes the first coating apparatus 40 (corresponding to one example of a “first processing apparatus”), the second coating apparatus 50 (corresponding to one example of a “second processing apparatus”), and the bonding apparatus 80. The first coating apparatus 40 includes the bonding agent injection part 431 configured to inject the bonding agent G. The first coating apparatus 40 coats the bonding agent G onto the support substrate S using the bonding agent injection part 431. The second coating apparatus 50 includes the bevel cleaning unit 55 configured to clean the bevel portion of the support substrate S coated with the bonding agent G. The bonding apparatus 80 bonds the support substrate S and the target substrate W using the bonding agent G and the release agent R which is smaller in bonding force than the bonding agent G. The second coating apparatus 50 further includes the release agent injection part 531 configured to inject the release agent R. The second coating apparatus 50 coats the release agent R onto the target substrate W using the release agent injection part 531.

According to the bonding system 1 of the first embodiment, it is therefore possible to reduce the number of apparatuses while preventing deterioration in the throughput.

Further, in some embodiments, the bonding system 1 includes the processing station 3 and the carry-in/carry-out station 2. Similarly, in the processing station 3, specified processes are performed with respect to the support substrate S (corresponding to one example of a “first substrate”) and the target substrate W (corresponding to one example of a “second substrate”). In the carry-in/carry-out station 2, the support substrate S, the target substrate W or the laminated substrate T is carried into and out of the processing station 3. The processing station 3 includes the first coating apparatus 40 (corresponding to one example of a “coating apparatus”), and the bonding apparatus 80. The first coating apparatus 40 widely coats the bonding agent G onto the surface of the support substrate S. The bonding apparatus 80 bonds the support substrate S and the target substrate W through the bonding agent G while heating the bonding agent G at a temperature lower than the hardening temperature of the bonding agent G. After the bonding process, the bonding apparatus 80 performs the temporary hardening process in which the laminated substrate T is heated from both sides of the support substrate S and the target substrate W at a temperature equal to or higher than the hardening temperature of the bonding agent G in a period of time shorter than the hardening time of the bonding agent G.

Therefore, according to the bonding system 1 of this embodiment, it is possible to appropriately perform the heat treatment for the laminated substrate T.

Further, in some embodiments, the bonding system 1 includes the processing station 3 and the carry-in/carry-out station 2. Similarly, in the processing station 3, specified processes are performed with respect to the support substrate S (corresponding to one example of a “first substrate”) and the target substrate W (corresponding to one example of a “second substrate”). In the carry-in/carry-out station 2, the support substrate S, the target substrate W or the laminated substrate T is carried into and out of the processing station 3. The processing station 3 includes the first coating apparatus 40 (corresponding to one example of a “first processing apparatus”), the second coating apparatus 50 (corresponding to one example of a “second processing apparatus”), the inspection unit 750, and the bonding apparatus 80. The first coating apparatus 40 includes the bonding agent injection part 431 configured to inject the bonding agent G. The first coating apparatus 40 coats the bonding agent G onto the support substrate S using the bonding agent injection part 431. The second coating apparatus 50 includes the bevel cleaning unit 55 configured to clean the bevel portion of the support substrate S coated with the bonding agent G. The inspection unit 750 inspects the surface state of the bevel portion of the support substrate S coated with the bonding agent G. The bonding apparatus 80 bonds the support substrate S and the target substrate W using the bonding agent G.

Therefore, according to the bonding system 1 of this embodiment, it is possible to determine, before the bonding process, whether the bonding agent G remains in the bevel portion of the support substrate S subjected to the bevel cleaning process. This prevents positions of the target substrate W and the support substrate S from being shifted in, e.g., the horizontal position adjusting process (Step S117) which is performed during the bonding process. Accordingly, it is possible to prevent productivity from being decreased by the position shift.

### Second Embodiment

While in the above embodiments, the support substrate S and the target substrate W has been described to be bonded using the bonding agent G and the release agent R, the present disclosure is not limited thereto. In some embodiments, the support substrate S and the target substrate W may be bonded using a protective agent which protects circuits, bumps and the like formed on the bonding surface Wj of the target substrate W, in addition to the bonding agent G and the release agent R.

In the second embodiment, a description will be made on a case where the support substrate S and the target substrate W are bonded using the bonding agent G, the release agent R and the protective agent. FIG. 17 is a schematic side view of a laminated substrate T obtained by bonding a target substrate W and a support substrate S according to the second embodiment. In the following description, components identical with those described with respect to the first embodiment will be designated by the same reference symbols as used in the foregoing description, and therefore, a description thereof will be omitted to avoid repetition.

As shown in FIG. 17, in the second embodiment, the support substrate S and the target substrate W are bonded using the bonding agent G, the release agent R and the protective agent P. The protective agent P, the release agent R and the bonding agent G are coated in the named order from the target substrate W side. Like the first embodiment, the uncoated region Q is formed in the target substrate W by the edge cut process.

Examples of the protective agent P may include a material which is smaller in bonding force and lower in viscosity than the bonding agent G. The protective agent P is soluble in an organic solvent such as a thinner, and is not hardened even when heated. A material which is larger in bonding force than the release agent R, may be used as the protective agent P.

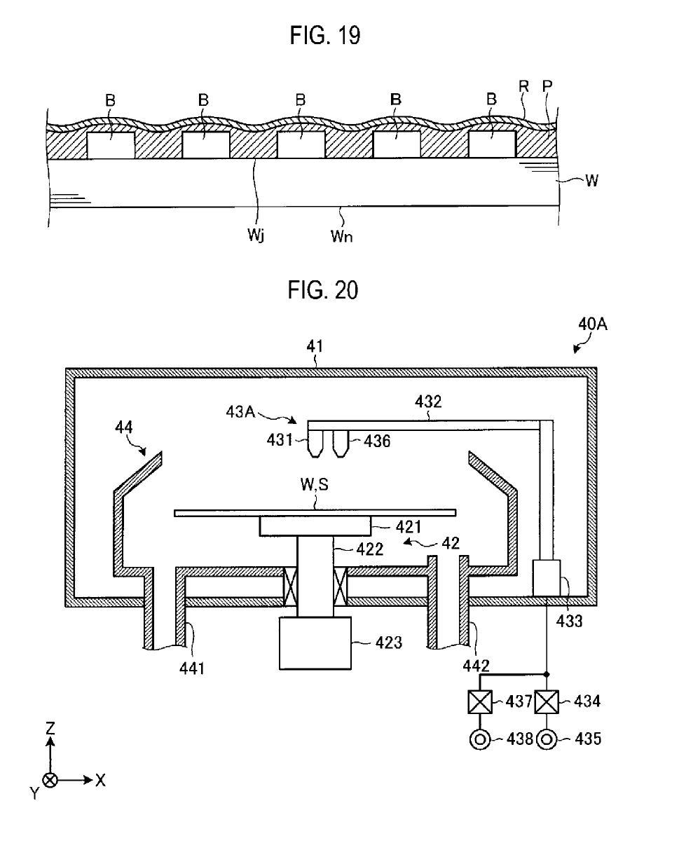

The protective agent P is coated on the target substrate W to protect circuits, bumps and the like, which are formed on the bonding surface Wj of the target substrate W. This will be described with reference to FIGS. 18 and 19. FIG. 18 is a schematic side view showing the bonding surface Wj of the target substrate W coated with the release agent R. FIG. 19 is a schematic side view showing the bonding surface Wj of the target substrate W coated with the protective agent P and the release agent R.

The release agent R is smaller in bonding force than the bonding agent G. As such, if the release agent R is coated at an increased thickness, the bonding force of the laminated substrate T becomes weak. For this reason, it is preferred that the release agent R is coated at a decreased thickness.

As shown in FIG. 18, bumps B and the like are formed on the bonding surface Wj of the target substrate W. As such, if the release agent R is coated at the decreased thickness, the bumps B may not be buried in the release agent R, which causes stepped portions on the bonding surface Wj coated with the release agent R. If the target substrate W is bonded to the support substrate S in a state where the stepped portions exist on the bonding surface Wj of the target substrate W, namely in a state where a surface area of the bonding surface Wj is large, the target substrate W and the support substrate S are strongly bonded by the bonding agent G. This causes a need for a large force when delaminating the target substrate W and the support substrate S.

On the other hand, in the second embodiment, as shown in FIG. 19, the protective agent P which is larger in bonding force than the release agent R is coated on the bonding surface Wj of the target substrate W while burying the bumps B. Thereafter, the release agent R is coated on the protective agent P. This makes it possible to coat the release agent R at the decreased thickness while reducing the surface area of the bonding surface Wj of the target substrate W. It is therefore possible to easily delaminate the target substrate W from the support substrate S in a subsequent delamination process.

Next, a configuration of a bonding system according to the second embodiment will be described with reference to FIG. 20. FIG. 20 is a schematic side view showing a configuration of a first coating apparatus provided in the bonding system according to the second embodiment.

The bonding system according to the second embodiment includes first coating apparatus 40A shown in FIG. 20, instead of the first coating apparatus 40 of the bonding system 1 according to the first embodiment.

As shown in FIG. 20, the first coating apparatus 40A includes a liquid supply unit 43A in place of the liquid supply unit 43 of the first coating apparatus 40. The liquid supply unit 43A further includes a protective agent injection part 436.

The protective agent injection part 436 is coupled to a protective agent supply source 438 through a valve 437. The protective agent injection part 436 injects the protective agent P supplied from the protective agent supply source 438 onto the target substrate W.

In order to reduce the viscosity of the protective agent P and to easily coat the protective agent P on the target substrate W, an organic solvent such as a thinner may be mixed with the protective agent P injected from the protective agent injection part 436.

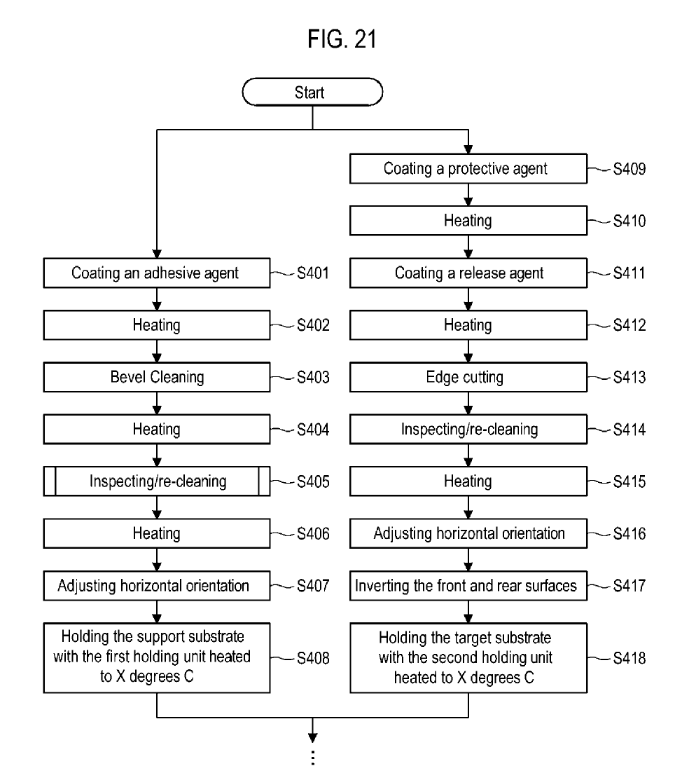

Next, a detailed operation of the bonding system according to the second embodiment will be described with reference to FIG. 21. FIG. 21 is a flowchart showing a sequence of processes implemented by the bonding system according to the second embodiment.

Processes performed after Step S418 in FIG. 21 are the same as the processes of Steps S117 to S121 shown in FIG. 11 and, therefore, are not shown in FIG. 21. In addition, processes of Steps S401 to S408 in FIG. 21 are the same as the processes of Steps S101 to S108 shown in FIG. 11 and, therefore, will not be described here.

As shown in FIG. 21, in the bonding system according to the second embodiment, a coating process of the protective agent P is performed prior to coating the target substrate W with the release agent R.

The target substrate W inside the cassette Cw is picked up by the first transfer device 14 and is transferred to the first delivery unit 20 of the processing station 3. At this time, the target substrate W is transferred with the non-bonding surface Wn thereof oriented downward. Subsequently, the target substrate W inside the first delivery unit 20 is picked up by the second transfer device 31 and is transferred to the first coating apparatus 40A as described above.

In the first coating apparatus 40A, a process of coating the protective agent P on the bonding surface Wj of the target substrate W is performed using the protective agent injection part 436 (in Step S409). Thus, a coating film of the protective agent P is formed on the bonding surface Wj of the target substrate W.

Subsequently, the target substrate W inside the first coating apparatus 40A is picked up by the second transfer device 31 and is transferred to the heat treatment apparatus 60.

In the heat treatment apparatus 60, a process of heating the target substrate W to a predetermined temperature is performed (in Step S410). This vaporizes the organic solvent included in the protective agent P which is coated on the target substrate W. Thereafter, the target substrate W is cooled down to a predetermined temperature, e.g., normal temperature, within the heat treatment apparatus 60. The protective agent P, from which the organic solvent is vaporized, becomes hard to the extent that the protective agent P does not flow down even when the target substrate W is tilted.

Thereafter, the target substrate W is bonded to the support substrate S after undergoing the processes of Steps S109 to S116 shown in FIG. 11 (in Steps S411 to S418).

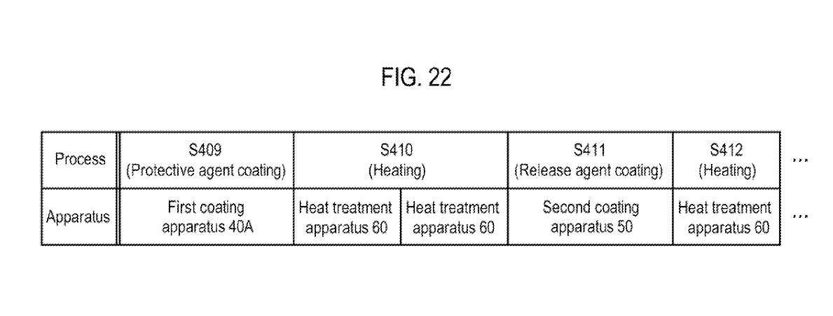

Next, the relationship between the aforementioned processes and respective apparatuses configured to perform the processes will be described with reference to FIG. 22. FIG. 22 is a view showing the relationship between the respective processes described above and the respective apparatuses configured to perform the processes. In FIG. 22, there are also shown the respective processes for the target substrate W.

As shown in FIG. 22, in the bonding system according to the second embodiment, the protective agent coating process (Step S409) and the release agent coating process (Step S411) are shown to be performed in different apparatuses. Assuming that these processes are performed by only the first coating apparatus 40A, a process time of the first coating apparatus 40A is prolonged. This may delay, e.g., the timing of transferring a subsequent target substrate W or a subsequent support substrate S into the first coating apparatus 40A, which results in deterioration in throughput. However, according to the bonding system of the second embodiment, the protective agent coating process and the release agent coating process are performed in different apparatuses, thus suppressing deterioration in throughput as compared with a case where the processes are performed in a single apparatus.

In the bonding system according to the second embodiment, the protective agent coating process for the target substrate W is performed by the first coating apparatus 40A which performs the bonding agent coating process for the support substrate S. That is to say, in the bonding system according to the second embodiment, the bonding agent coating process for the support substrate S and the protective agent coating process for the target substrate W are performed through the use of a common apparatus. Therefore, according to the bonding system of the second embodiment, as compared with a case where the processes are performed in different apparatuses, it is possible to reduce the number of apparatuses.

In the bonding system according to the second embodiment, during the heating process of Step S410, the heating process of the target substrate W is performed at two stages using the heat treatment apparatus 60. Specifically, the heat treatment apparatus 60 performs a secondary heating process of heating the target substrate W at a higher temperature than that of a primary heating process. Such a staged heating process for the target substrate W prevents irregularities from being generated in a surface of the protective agent P due to bumping of the protective agent P or other causes. This staged heating process may be performed in other heating processes.

### Third Embodiment

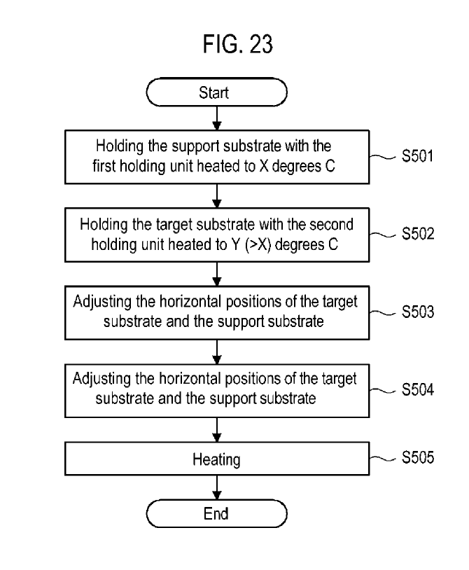

In a third embodiment, a modified example of the bonding and temporary hardening processes will be described with reference to FIG. 23. FIG. 23 is a flowchart showing a sequence of bonding and temporary hardening processes according to the third embodiment.

As shown in FIG. 23, the bonding unit 85 holds the support substrate S using the first holding unit 110 which is preheated to X degrees C., namely the softening temperature (120 to 140 degrees C.) of the bonding agent G, by the first heating mechanism 130 (in Step S501). Thus, the bonding agent G coated on the support substrate S is softened.

Subsequently, the bonding unit 85 holds the target substrate W using the second holding unit 120 which is preheated to Y degrees C. (e.g., 200 degrees C.) equal to or higher than the hardening temperature (about 180 degrees C.) of the bonding agent G by the second heating mechanism 140 (in Step S502). The protective agent P and the release agent R which are coated on the target substrate W, have such a property that they are not hardened even when heated. As such, the protective agent P and the release agent R are not hardened even if they are heated to Y degrees C. The processes of Steps S501 and S502 may be performed in the reverse order.

Thereafter, the bonding unit 85 adjusts horizontal positions of the target substrate W and the support substrate S (in Step S503), followed by moving the second holding unit 120 downward using the pressing mechanism 150 such that the target substrate W is brought into contact with the support substrate S (in Step S504), followed by pressing the target substrate W and the support substrate S against each other (in Step S505).

In this way, the target substrate W and the support substrate S are initially bonded through the bonding agent G, the release agent R and the protective agent P. As the target substrate W and the support substrate S make contact with each other, heat of the target substrate W is radiated to the bonding agent G coated on the support substrate S. Such a heat radiation increases a temperature of the bonding agent G so that the bonding agent G begins to harden. Prior to the bonding agent G being completely hardened, the bonding unit 85 stops the heating processes performed by the first heating mechanism 130 and the second heating mechanism 140. Consequently, the bonding agent G is hardened to the extent that the bonding agent G is not completely hardened.

As described above, the bonding unit 85 heats the first holding unit 110 which holds the support substrate S to the softening temperature of the bonding agent G, and heats the second holding unit 120 which holds the target substrate W to the temperature equal to or higher than the hardening temperature of the bonding agent G. In this state, the bonding unit 85 brings the support substrate S into contact with the target substrate W and presses the support substrate S and the target substrate W against each other. This configuration allows the bonding process and the temporary hardening process to be performed in parallel, thus improving throughput.

In this case, a difference in temperature is generated between both sides of the support substrate S and the target substrate W in the laminated substrate T, which may result in deformation of the laminated substrate T. However, the bonding unit 85 performs the temporary hardening process on the laminated substrate T in a state where the support substrate S and the target substrate W are pressed against each other, thus suppressing the deformation of the laminated substrate T.

### Fourth Embodiment

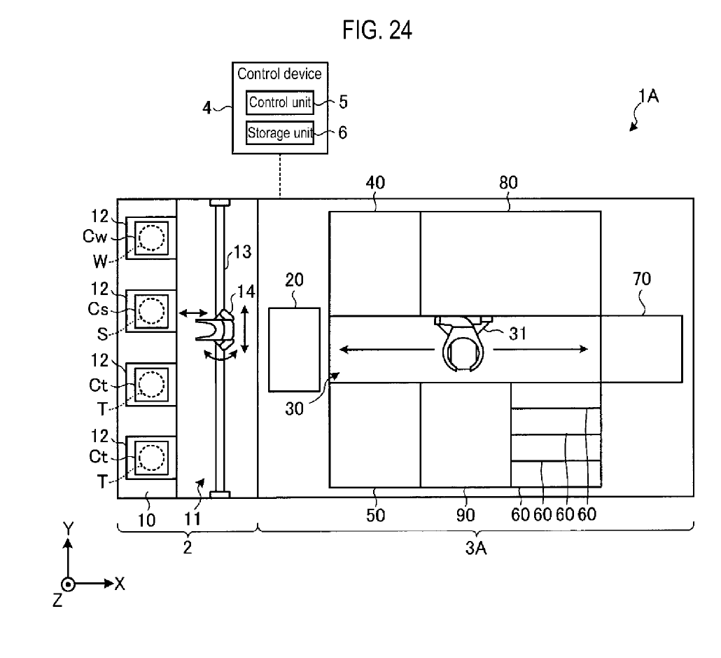

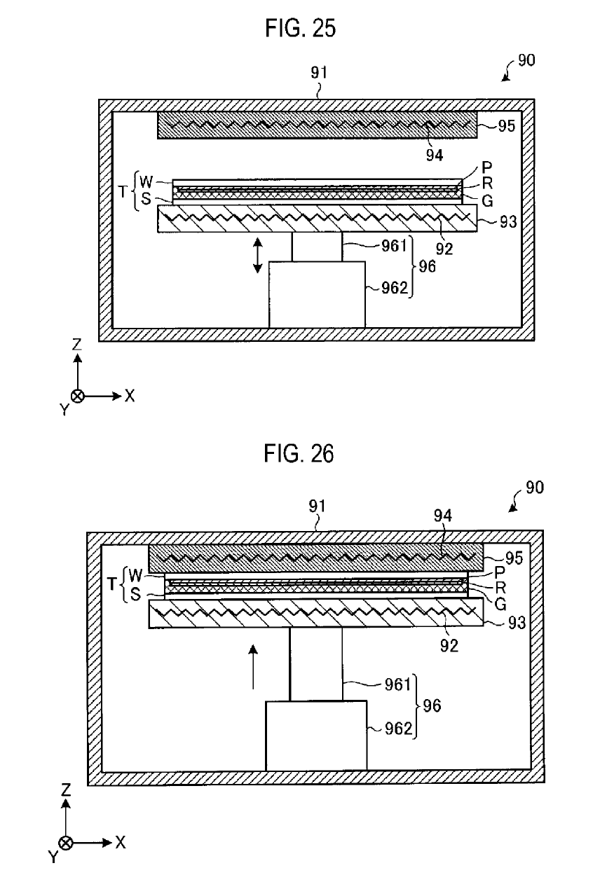

While in the above embodiments, the temporary hardening process has been described to be performed using the bonding apparatus 80 which performs the bonding process, the temporary hardening process may be performed using a dedicated apparatus. This will be described with reference to FIGS. 24 to 26. FIG. 24 is a schematic plane view showing a configuration of a bonding system according to a fourth embodiment. FIGS. 25 and 26 are schematic side views showing a configuration of a temporary hardening apparatus provided in the bonding system according to the fourth embodiment.

As shown in FIG. 24, the bonding system lA according to the fourth embodiment includes a temporary hardening apparatus 90 provided in a processing station 3A. The temporary hardening apparatus 90 is disposed adjacent to the second transfer zone 30 similar to other apparatuses.

As shown in FIG. 25, the temporary hardening apparatus 90 includes a hermetically sealable processing container 91. The processing container 91 includes an inlet/outlet (not shown) formed in a side facing the second transfer zone 30. An opening/closing shutter (not shown) is installed in the inlet/outlet.

Within the processing container 91, there are installed a first plate 93 and a second plate 95. The first plate 93 includes a heating mechanism 92 and is disposed at a side of the support substrate S of the laminated substrate T. The second plate 95 includes a heating mechanism 94 and is disposed at a side of the target substrate W in the laminated substrate T. While in FIG. 25, the first plate 93 has been shown to be disposed below the second plate 95, the first plate 93 may be disposed above the second plate 95.

Further, a pressing mechanism 96 is disposed within the processing container 91. The pressing mechanism 96 includes a post member 961 to support the first plate 93 and a moving mechanism 962 configured to vertically move the post member 961.

The temporary hardening apparatus 90 configured as above moves the first plate 93 upward using the pressing mechanism 96 after the laminated substrate T is loaded on the first plate 93 by the second transfer device 31. Thus, the temporary hardening apparatus 90 brings the target substrate W of the laminated substrate T into contact with the second plate 95 such that the laminated substrate T and the second plate 95 are pressed against each other.

Thereafter, the temporary hardening apparatus 90 heats the first plate 93 and the second plate 95 to a temperature equal to or higher than the hardening temperature (about 180 degrees C.) of the bonding agent G, e.g., 200 degrees C., using the heating mechanisms 92 and 94. Then, prior to the bonding agent G being completely hardened, the temporary hardening apparatus 90 stops the heating processes of the heating mechanisms 92 and 94. Thus, the bonding agent G is hardened to the extent that the bonding agent G is not completely hardened.

As described above, the temporary hardening process may be performed using the dedicated apparatus (i.e., the temporary hardening apparatus 90) instead of the bonding apparatus 80. Unlike the bonding process, the temporary hardening process may not be performed under a depressurized atmosphere. This eliminates a need for the temporary hardening apparatus 90 to include the depressurizing unit 180 as described above.

### Fifth Embodiment

While in the above embodiments, the inspection unit 750 has been described to be disposed in the edge cut apparatus 70 where the inspecting/recleaning process for the support substrate S is performed, the inspecting/recleaning process may be performed by, e.g., the second coating apparatus 50 which performs the bevel cleaning process for the support substrate S.

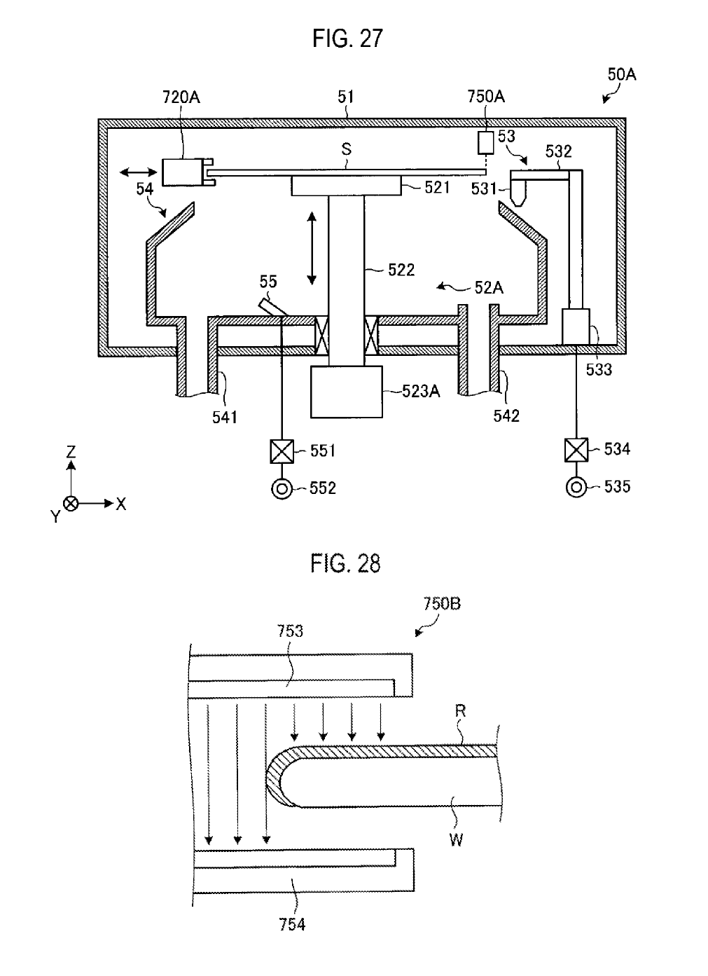

This will be described with reference to FIG. 27. FIG. 27 is a schematic side view showing a configuration of a second coating apparatus according a fifth embodiment.

As shown in FIG. 27, the second coating apparatus 50A according to the fifth embodiment further includes a solvent supply unit 720A and an inspection unit 750A.

The solvent supply unit 720A and the inspection unit 750A are disposed above a collection cup 54. The solvent supply unit 720A is horizontally movable by a moving mechanism (not shown). Similar to the solvent supply unit 720 shown in FIG. 7, the solvent supply unit 720A is coupled to an organic solvent supply source through a supply kit including a valve, a flow rate controller and the like.

The second coating apparatus 50A includes a substrate holding mechanism 52A. The substrate holding mechanism 52A includes a drive unit 523A configured to rotate a post member 522 about a vertical axis and to move the post member 522 in the vertical direction.

The second coating apparatus 50A configured as above performs the bevel cleaning process using the bevel cleaning unit 55 and subsequently, moves the support substrate S upward beyond the collection cup 54 using the substrate holding mechanism 52A.

Subsequently, the second coating apparatus 50A inspects the surface state of the bevel portion of the support substrate S using the inspection unit 750A, while rotating the support substrate S using the substrate holding mechanism 52A. If it is determined as a result of this inspection that the bonding agent G remains in the bevel portion of the support substrate S, the second coating apparatus 50A moves the solvent supply unit 720A to locate the solvent supply unit 720A in the peripheral portion of the support substrate S.

Then, the second coating apparatus 50A injects an organic solvent such as a thinner toward front and rear surfaces of the peripheral portion of the support substrate S including the bevel portion using the solvent supply unit 720A, thereby removing the bonding agent G adhering to the peripheral portion of the support substrate S.

As described above, the second coating apparatus 50A which is configured to perform the bevel cleaning process for the support substrate S, may also perform the inspecting/recleaning process for the support substrate S.

While in this embodiment, the inspecting/recleaning process has been described to be performed just after the bevel cleaning process, the inspecting/recleaning process may be performed after the bevel cleaning process followed by the heating process, similar to the first embodiment. In this case, the support substrate S subjected to the bevel cleaning process may be first taken out from the second coating apparatus 50A and may be carried into the heat treatment apparatus 60. Subsequently, the support substrate S subjected to the heating process may be carried into the second coating apparatus 50A again.

### Other Embodiments

While in the above embodiments, the inspection unit 750 or 750A has been described to the CCD camera, the present disclosure is not limited thereto. Another example of the inspection unit will be described with reference to FIG. 28. FIG. 28 is a schematic side view showing a configuration of an inspection unit 750B according to a modified example.

As shown in FIG. 28, instead of the CCD camera, a transmission-type photo sensor may be used as the inspection unit 750B.

The inspection unit 750B includes a light emitting element 753 and a light receiving element 754. In FIG. 28, the light emitting element 753 is arranged at the side of the bonding surface Wj of the target substrate W and the light receiving element 754 is arranged at the side of the non-bonding surface Wn of the target substrate W. This arrangement may be reversed.

In the inspection unit 750B, light is irradiated from the light emitting element 753 toward the light receiving element 754. The light not interrupted by the target substrate W is incident upon the light receiving element 754. This makes it possible to detect a shape of the bevel portion of the target substrate W. Based on the detection result of the inspection unit 750B, the control unit 5 determines whether, for example, the release agent R remains in the bevel portion of the target substrate W.

In the above embodiments, the bevel portion has been described to be recleaned when the bonding agent G, the release agent R or the protective agent P remains in the bevel portion of the support substrate S or the target substrate W. In some embodiments, the bevel portion may be recleaned only when the bonding agent G, the release agent R or the protective agent P remains in a specific region of the bevel portion of the support substrate S or the target substrate W.

As an example, the bevel portion of the support substrate S may be recleaned when the bonding agent G exists at a location of the bevel portion of the support substrate S at which the reference point used in adjusting the horizontal position is formed. Similarly, the bevel portion of the target substrate W may be recleaned when the release agent R or the protective agent P exists at a location of the bevel portion of the target substrate W at which the reference point used in adjusting the horizontal position is formed. This makes it possible to shorten a period of time required for the inspecting/recleaning process.

In some embodiments, in the bonding system, the bevel portion of the support substrate S may be recleaned when the bonding agent G exists in a location of the bevel portion of the support substrate S at which a notch used in adjusting the horizontal position is formed. Similarly, the bevel portion of the target substrate W may be recleaned when the release agent R or the protective agent P exists in the notch formed in the bevel portion of the support substrate S. This makes it possible to shorten a period of time required for the inspecting/recleaning process.

While in the above embodiments, the support substrate S and the target substrate W have been described to examples of the first and second substrates, respectively, they may be reversed. As an example, the bonding agent G may be coated on the target substrate W, and the release agent R may be coated on the support substrate S.

While in the above embodiments, the pressing mechanism 150 has been described to move the second holding unit 120 downward such that the target substrate W is brought into contact with the support substrate S, thus pressing the target substrate W and the support substrate S against each other, the present disclosure is not limited thereto. As an example, the pressing mechanism 150 may move the first holding unit 110 upward such that the support substrate S is brought into contact with the target substrate W, thus pressing the target substrate W and the support substrate S against each other.

According to the present disclosure in some embodiments, it is possible to reduce the number of apparatuses while preventing deterioration in throughput.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A bonding system, comprising:
a processing station in which specified processes are performed on a first substrate and a second substrate; and
a carry-in/carry-out station in which the first substrate, the second substrate or a laminated substrate obtained by bonding the first substrate and the second substrate is carried into and out of the processing station,
wherein the processing station includes:
a first processing apparatus provided with an bonding agent injection part for injecting an bonding agent and configured to coat the first substrate with the bonding agent using the bonding agent injecting part;
a second processing apparatus provided with a bevel cleaning unit for cleaning a bevel portion of the first substrate coated with the bonding agent; and
a bonding apparatus configured to bond the first substrate and the second substrate through the bonding agent and a release agent which is smaller in bonding force than the bonding agent,
wherein the first processing apparatus or the second processing apparatus further includes a release agent injection part for injecting the release agent, and is configured to coat the release agent on the second substrate using the release agent injecting part.

2. The system of claim 1, wherein the release agent injection part is installed in the second processing apparatus.

3. The system of claim 1, further comprising: a heat treatment apparatus configured to heat the first substrate to a predetermined temperature after the first substrate is coated with the bonding agent by the first processing apparatus and before the bevel portion is cleaned by the second processing apparatus.

4. The system of claim 1, further comprising: an edge cut apparatus provided with a chemical solution injection unit for injecting a chemical solution toward front and rear surfaces of a peripheral portion of the second substrate including a bevel portion,
wherein the edge cut apparatus is configured to remove the release agent from the peripheral portion of the second substrate using the chemical solution injecting unit.

5. The system of claim 1, wherein the first processing apparatus or the second processing apparatus further includes a protective agent injection part for injecting a protective agent which is smaller in bonding force than the bonding agent,
wherein the first processing apparatus or the second processing apparatus including the protective agent injection part is configured to coat the second substrate with the protective agent using the protective agent injecting part.

6. The system of claim 5, wherein the protective agent injection part is installed in the first processing apparatus.

7. The system of claim 5, wherein the release agent injection part is installed in the second processing apparatus, and the protective agent injection part is installed in the first processing apparatus.

8. The system of claim 1, wherein the bonding apparatus includes:
a first holding unit configured to hold the first substrate;
a second holding unit configured to hold the second substrate;
a first heating mechanism configured to heat the first holding unit;
a second heating mechanism configured to heat the second holding unit;
a pressing mechanism configured to move the first holding unit and the second holding unit such that the first substrate and the second substrate are brought into contact with each other through the bonding agent, and configured to press the first substrate and the second substrate against each other; and
a control unit configured to control the first heating mechanism, the second heating mechanism and the pressing mechanism to perform a bonding process in which the first substrate and the second substrate are bonded through the bonding agent while heating the bonding agent at a temperature lower than a hardening temperature of the bonding agent, and a temporary hardening process in which, after the bonding process, the laminated substrate obtained by bonding the first substrate and the second substrate is heated at a temperature equal to or higher than the hardening temperature of the bonding agent for a time shorter than a hardening time of the bonding agent.

9. The system of claim 1, wherein the processing station further includes a temporary hardening apparatus configured to heat the laminated substrate obtained by bonding the first substrate and the second substrate, at a temperature equal to or higher than a hardening temperature of the bonding agent for a time shorter than a hardening time of the bonding agent.

10. The system of claim 9, wherein the temporary hardening apparatus includes:
a first plate provided with a heating mechanism and configured to face a surface of the laminated substrate existing at the side of the first substrate;
a second plate provided with a heating mechanism and configured to face a surface of the laminated substrate existing at the side of the second substrate; and
a pressing mechanism configured to move the first plate and the second plate to thereby press the laminated substrate with the first plate and the second plate.

11. A bonding method, comprising:
a first coating process in which a bonding agent is coated on a first substrate using a first processing apparatus provided with a bonding agent injection part for injecting the bonding agent;
a bevel cleaning process in which a bevel portion of the first substrate subjected to the first coating process is cleaned using a second processing apparatus provided with a bevel cleaning unit for cleaning the bevel portion of the first substrate;
a second coating process in which a release agent lower in bonding force than the bonding agent is coated on a second substrate using a release agent injection part for injecting the release agent; and
a bonding process in which the first substrate and the second substrate are bonded through the bonding agent and the release agent,
wherein the second coating process is performed in the first processing apparatus or the second processing apparatus.
